(19) United States
(12) Patent Application Publication
(10) Pub. No.: US 2004/0173894 A1
(43) Pub. Date: Sep. 9, 2004

(54) INTEGRATED CIRCUIT PACKAGE INCLUDING INTERCONNECTION POSTS FOR MULTIPLE ELECTRICAL CONNECTIONS

(75) Inventors: Mr. Thomas P. Glenn, Gilbert, AZ (US); Mr. Steven Webster, Chandler, AZ (US)

Correspondence Address: BEVER HOFFMAN & HARMS, LLP, TRI-VALLEY OFFICE, 1432 CONCANNON BLVD., BLDG. G, LIVERMORE, CA, 94550, US

(73) Assignee: Amkor Technology, Inc., Chandler, AZ (US)

(21) Appl. No.: 09/966,841

(22) Filed: Sep. 27, 2001

(51) Int. Cl. H01L 23/48

(52) U.S. Cl. 257/693; 257/697; 257/698

(57) ABSTRACT

### Abstract of the Disclosure

FileNameFileName-33-Integrated circuit packages including interconnection posts with multiple metal terminals are disclosed. An exemplary package includes a molded plastic body with integral plastic posts extending from the body. Each post is coated with a plurality of electrically separate metal terminals. The metal terminals extend from a surface of the body, along a sidewall of a respective post, to an end of the post. An integrated circuit is mounted on the body. Conductive paths, which may include vias through the body, electrically couple different bond pads of the integrated circuit to the metal terminals of the posts. In some embodiments, posts on opposing sides of the plastic body enable stacking, and electrical coupling, of two or more packages. The metal terminals of posts of the lower package may be engaged with the metal terminals of corresponding posts on a mounting substrate.

### Detailed Description of the Invention

### Background of Invention

In the field of integrated circuit packaging, an integrated circuit (also called a chip or a semiconductor chip) communicates with external circuitry through a plurality of external terminals of a package. Typically, a single electrical connection to the integrated circuit is made through each external terminal. Many integrated circuits, especially those with high functionality, require large numbers of external connections, and hence, large numbers of external terminals. Such packages can thus occupy large areas of the printed circuit boards upon which they are mounted.

Artisans have attempted to conserve the area of printed circuit boards by including a plurality of integrated circuits in a single package body, or by stacking separate packages on top of each other. These solutions allow an increase in package density and function without a significant increase in the area of a printed circuit board that is occupied by the package, or stack, mounted thereon.

A significant disadvantage of these conventional solutions, even packages including a plurality of integrated circuits or stacks of packages, is that the area required on the printed circuit board is not directly reduced. The area required by the package can be large, limiting the total number of packages that can be placed side-by-side on a given area of a printed circuit board.

Accordingly, a package with a higher external terminal density is desirable.

### Summary of Invention

Embodiments of the present invention include economical integrated circuit packages and mounting substrates (e.g., sockets or motherboards) that allow for a large number of reliable, yet non-permanent, connections. A component of the exemplary packages and mounting substrates is a molded plastic body including integral plastic posts extending from the body. A sidewall of the posts is coated with metal, and may include a plurality of electrically separate metal coatings. The posts of a plurality of packages may be frictionally engaged with each other to allow the formation of an electrically interconnected stack of packages. Similarly, the posts of one or more of the packages may be frictionally engaged with the posts of a mounting substrate, which in turn has input/output terminals that allow for external electrical connections.

In accordance with one embodiment of the present invention, an integrated circuit package using an embodiment of the above-described substrate includes an integrated circuit including a plurality of bond pads. The integrated circuit is mounted on the body and electrically coupled to at least some of the paths through the bond pads. The bond pads of the integrated circuit may be electrically coupled to the paths by a plurality of bond wires. The integrated circuit may be encapsulated, at least in part, by an encapsulant material.

Another embodiment of the present invention includes a stack of integrated circuit packages. The stack includes a first integrated circuit package including a first integrated circuit mounted on a first molded plastic body of a first substrate. The first substrate also includes a plurality of first plastic posts extending integrally from the first molded plastic body, and a plurality of electrically separate first metal terminals coating a sidewall of at least one of the first plastic posts. The stack also includes a second integrated circuit package including a second integrated circuit mounted on a second molded plastic body of a second substrate. The second substrate includes a plurality of second plastic posts extending integrally from the second molded plastic body, and may further include a plurality of electrically separate second metal terminals coating a sidewall of at least one of the second plastic posts. The first and second integrated circuit packages are stacked, and at least some of the first plastic posts are engaged with at least some of the second plastic posts so that the first metal terminals are electrically coupled to respective ones of the second metal terminals.

The present invention also includes a mounting substrate upon which one or more integrated circuit packages may easily be mounted. The mounting substrate includes a molded plastic sheet, a plurality of plastic posts each extending integrally from the sheet, and a plurality of electrically separate metal terminals coating a sidewall of at least one of the posts. The mounting substrate also includes a plurality of electrically conductive input/output terminals at a periphery of the sheet. The input/output terminals are adapted to electrically couple the substrate to circuitry external to the substrate. The mounting substrate also includes a plurality of electrically conductive traces each electrically coupled at first ends to a respective one of the metal terminals. At least some of the traces are electrically coupled at opposite second ends to respective ones of the electrically conductive input/output terminals.The present invention is best understood by reference to the following detailed description when read in conjunction with the accompanying drawings.

### Brief Description of Drawings

Figure 1 is a cross-sectional side view of an integrated circuit package in accordance with one embodiment of the present invention.

Figure 2 is a plan view of a portion of an upper side of the body of the integrated circuit package of Figure 1.

Figure 3 is a plan view of a portion of a lower side of the body of the integrated circuit package of Figure 1.

Figure 4 is a cross-sectional side view of an assembly including the integrated circuit package of Figure 1 mounted on a mounting substrate.

Figure 5 is a plan view of a portion of the assembly of Figure 4 through the line 5-5.

Figure 6A is a plan view of a post geometry in accordance with an alternative embodiment of the present invention.

Figure 6B is a cross-sectional side view of the post geometry of Figure 6A through the line 6B-6B.

Figure 7A is a plan view of a post geometry in accordance with an alternative embodiment of the present invention.

Figure 7B is a cross-sectional side view of the post geometry of Figure 7A through the line 7B-7B.

Figure 8A is a cross-sectional side view of an integrated circuit package in accordance with an alternative embodiment of the present invention.

Figure 8B is a cross-sectional side view of the integrated circuit package of Figure 8A mounted on a mounting substrate, which is mounted on a printed circuit board.

Figure 9 is a cross-sectional side view of a stackable integrated circuit package in accordance with an alternative embodiment of the present invention.

Figure 10 is a plan view of a portion of the upper side of the body of the stackable integrated circuit package of Figure 9.

Figure 11 is a cross-sectional side view of a stack including two packages of Figure 9 stacked together and mounted on a mounting substrate, which is mounted on a printed circuit board.

Figure 12 is a plan view of a portion of the stack of Figure 11 through the line 12-12.

Figure 13 is a cross-sectional side view of a plastic mounting substrate that may be used for mounting packages disclosed herein in accordance with the present invention.

Figure 14 is a flow chart outlining a method of making substrates for integrated circuit packages in accordance with the present invention.

Figure 15 is a flow chart outlining a method of making integrated circuit packages in accordance with the present invention.

Figure 16 shows plan views of post geometries in accordance with alternative embodiments of the present invention.

Figure 17 shows plan views of post geometries in accordance with alternative embodiments of the present invention.

Common reference numerals are used throughout the drawings and detailed description to indicate like elements. Structures having minor variations to previously described structures (e.g., substrate 12 or post 18) may be identified by addition of a letter (e.g., substrate 12a) or one or more prime marks (e.g., post 18" or post 18""). The variations are explained and redundant detail vis-à-vis the previously described structure typically is omitted.

### Detailed Description

The structures and methods disclosed herein have similarity to those disclosed in the following U. S. patent applications, which are incorporated herein by reference in their respective entireties:U.S. Application Serial No. 09/881,344, entitled "Integrated Circuit Package Having Posts For Connection To Other Packages And Substrates,"filed June 13, 2001.

U.S. Application Serial No. 09/827,619, entitled "Semiconductor Package With Molded Substrate And Recessed Input/Output Terminals,"filed April 6, 2001.

U.S. Application Serial No. [Attorney Docket No. M-8921 US], entitled "Integrated Circuit Package Including Pin and Barrel Interconnects,"filed August 16, 2001.

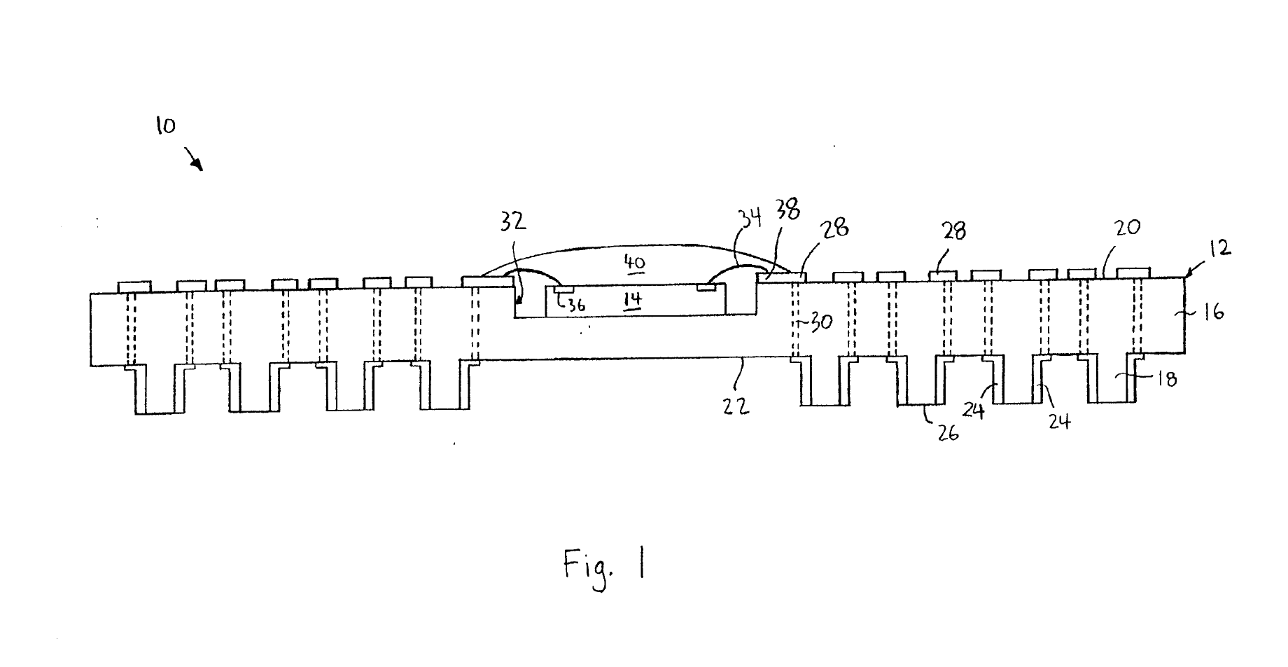

Figure 1 is a cross-sectional side view of an integrated circuit package 10 in accordance with one embodiment of the present invention. The design of package 10 enables an increased density of external package terminals for a given number of package posts. Package 10 includes a substrate 12 upon which an integrated circuit 14 is mounted. Substrate 12 includes a substantially planar, insulative, molded plastic body 16 and a plurality of plastic posts 18, each integrally connected to body 16. Substrate 12 may be formed by injection molding of a liquid crystal polymer ("LCP") material or of another plastic material. The material selected for substrate 12 should be able to withstand the temperatures of conventional solder reflowing operations. Substrate 12 may also include electrically conductive metallizations, discussed in more detail below.

Body 16 includes a planar upper side 20 and an opposite planar lower side 22. Each of plastic posts 18 is cylindrical and projects vertically from lower side 22. Posts 18 are formed of the same material as body 16, are integral with body 16, and are formed in the same molding step.

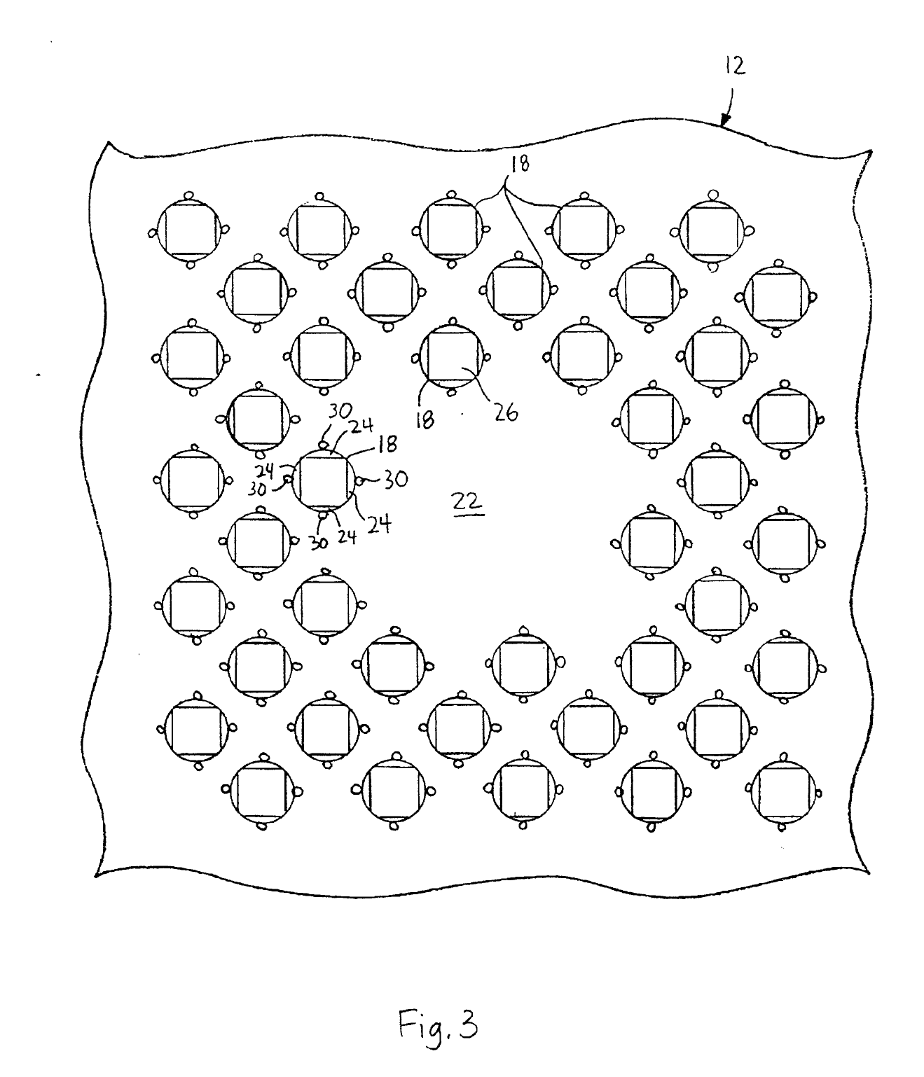

Substrate 12 also includes four external metal terminals 24 that are equally spaced, but electrically separate, on the exterior sidewall of each post 18. In the cross-sectional side view of Figure 1, only two metal terminals 24 per post 18 are seen. The other two metal terminals 24 per post 18 are located in the third dimension, outside of the plane of Figure 1 (see, e.g., Figure 3). Each metal terminal 24 is a coating on a portion of the sidewall of a respective post 18. Metal terminals 24 each extend from the surface of lower side 22 surrounding a respective post 18, along the exterior sidewall of post 18, to an end 26 of post 18. Each metal terminal 24 may extend partly onto the surface of end 26 of the respective post 18.

Metal terminals 24 are each electrically coupled to a respective one of a plurality of electrically conductive traces 28 on upper side 20. A plurality of metal-coated vias 30 extending from upper side 20, through body 16, to lower side 22 electrically couple respective traces 28 on upper side 20 to respective metal terminals 24 on posts 18. The number of posts 18, metal terminals 24, traces 28, and vias 30 will vary with the functionality of integrated circuit 14. The diameter of each via 30, which may be 0.05is less than the diameter of each post 18, which may be d_{p = 0.5-2 mm.}

Integrated circuit 14 is mounted in a rectangular recess 32 in upper side 20 of body 16. A conventional die attach adhesive, such as epoxy, tape, or an adhesive film, may be used to attach integrated circuit 14 to body 16. Integrated circuit 14 is electrically coupled to conductive traces 28 on upper side 20 of body 16 by a plurality of metal bond wires 34 (e.g., gold wires). Each bond wire 34 is electrically coupled between an electrically conductive bond pad 36 of integrated circuit 14 and a leadfinger 38 at an inner end of a respective trace 28. Leadfingers 38 may be adjacent to two or all four sides of recess 32. Each trace 28 is electrically coupled to a respective metal-coated via 30. Leadfingers 38, traces 28, metal-coated vias 30, and metal terminals 24 on posts 18 thus form conductive paths (to which integrated circuit 14 is coupled) on and through substrate 12 of package 10. Alternatively, a plurality of integrated circuits 14 could be provided in recess 32. Further, passive devices (such as resistors, capacitors, or inductors) could be electrically connected to integrated circuit 14 in recess 32, or to traces 28 on body 16.

A hardened encapsulant 40 on upper side 20 fills recess 32 and covers integrated circuit 14, bond wires 34, and leadfingers 38. Encapsulant 40 is insulative and protects integrated circuit 14 from the environment. Encapsulant 40 may be Hysol® 4450 or 4423 encapsulants from the Dexter Hysol Company of Industry, CA, or some other conventional encapsulant. Encapsulant 40 may be omitted, or replaced with an opaque or transparent planar lid attached onto upper side 20 that covers recess 32 and integrated circuit 14, depending on the application.

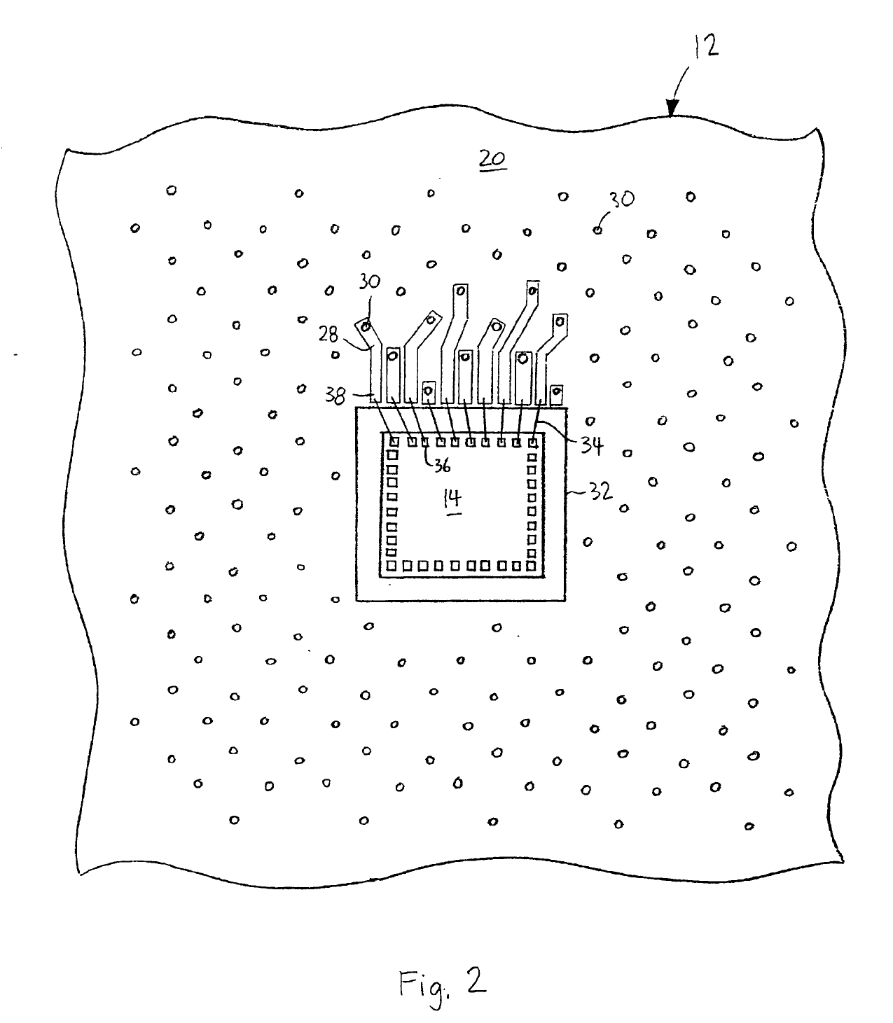

Figure 2 is a plan view of a portion of upper side 20 of body 16 of integrated circuit package 10 of Figure 1. Bond pads 36 on integrated circuit 14 are electrically coupled to leadfingers 38 of respective traces 28 by bond wires 34. The end of each trace 28, opposite to leadfinger 38, is coupled to a respective metal-coated via 30. Metal-coated vias 30 each extend through body 16 to lower side 22, eventually leading to a respective metal terminal 24 on a respective post 18. In the embodiment of Figure 3, only a representative sample of bond pads 36, bond wires 34, leadfingers 38, and traces 28 are shown. Typically, for example, bond pads 36 may be arranged along two or all four sides of integrated circuit 14, and leadfingers 38 and traces 28 would be located proximate to the respective bond pads 36. Artisans will appreciate that in practice most, if not all, of vias 30 will actually be electrically coupled to a respective bond pad 36 of integrated circuit 14 through traces 28 as described above.

Figure 3 is a plan view of a portion of lower side 22 of body 16 of integrated circuit package 10 of Figure 1. Figure 3 shows a checkerboard arrangement of posts 18 on lower side 22. Each of the four separate metal terminals 24 on the sidewall of a respective post 18 is shown extending partly onto the surface of end 26 of the post 18. Four metal-coated vias 30 are adjacent to each post 18 and are electrically coupled to a respective metal terminal 24. Metal terminals 24 of posts 18 are each electrically coupled to a respective one of vias 30. Accordingly, all or selected bond pads 36 of integrated circuit 14 are each electrically coupled to a respective metal terminal 24 on a respective post 18 on lower side 22 of body 16. In other words, each post 18 can serve as an input/output (I/O) terminal for four bond pads 36 of integrated circuit 14, since an electrically separate conductive path extends to each of the four metal terminals 24 on each post 18.

Artisans will appreciate that the number and arrangement of posts 18 can vary. The arrangement may vary depending, for example, on the number of input/output terminals needed on package 10 to accommodate the particular integrated circuit 14 (or multiple integrated circuits) mounted therein, or on the configuration of the printed circuit board (or other substrate) on which package 10 is mounted. For instance, instead of having a checkerboard pattern, posts 18 may be arranged in a grid array, or in a pair of rows, or in a square pattern, among other possibilities.

Artisans will also appreciate that the location of vias 30 may vary. In the embodiment of Figure 3, each via 30 is shown abutting a respective post 18 at the midpoint of a respective metal terminal 24. In practice, vias 30 may be rotated about post 18 so that they each contact a respective metal terminal 24 at an off-center point. Further, vias 30 may be spaced farther from posts 18, with each such via 30 being electrically coupled to a respective metal terminal 24 by a conductive trace (not shown).

Package 10 of Figure 1 through Figure 3 thus increases the density of external package input/output terminals (e.g., metal terminals 24) by four, compared to conventional packages. In addition, the pitch between posts 18 is reduced compared to conventional packages. In fact, the package pitch, which may be about 0.04 mm is reduced below the pitch between bonding pads on integrated circuit 14, which may be 0.10 mm. An integrated circuit in a flip chip configuration may have a pitch of 0.05 mm. Thus, a decrease in the physical size of integrated circuit 14 (made possible by advances in technology) is propagated to integrated circuit package 10. This allows package 10 to occupy less space on a printed circuit board than is required by a conventional package.

Package 10 of Figure 1 through Figure 3 can be mounted directly on a conventional printed circuit board using conventional soldering and reflow techniques. Due to the small dimensions of posts 18 and metal terminals 24, however, alignment of such an assembly may be somewhat difficult.

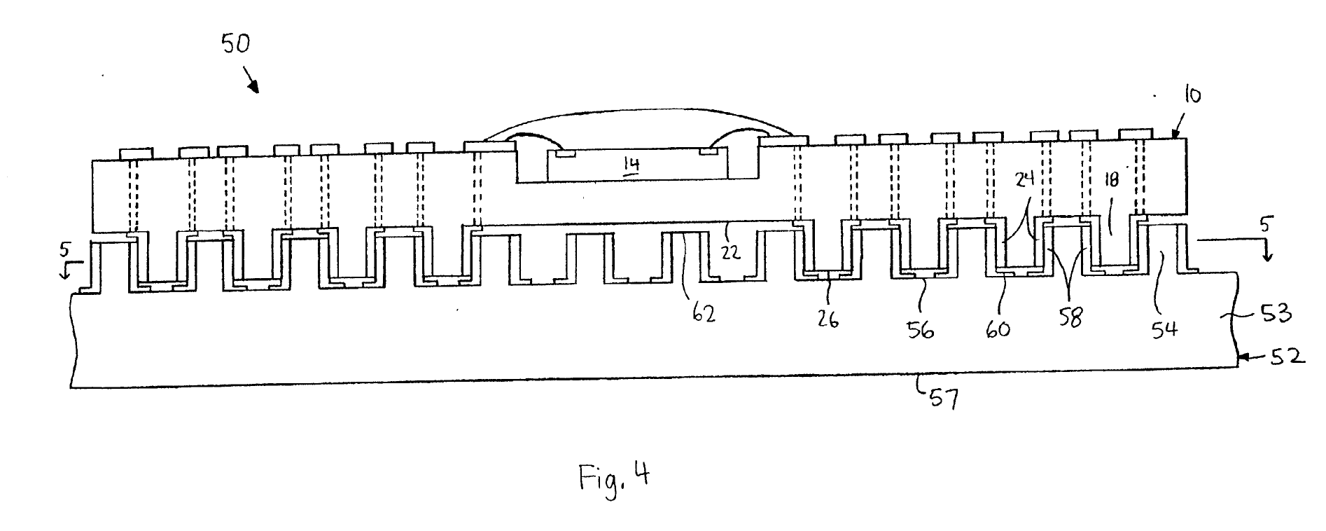

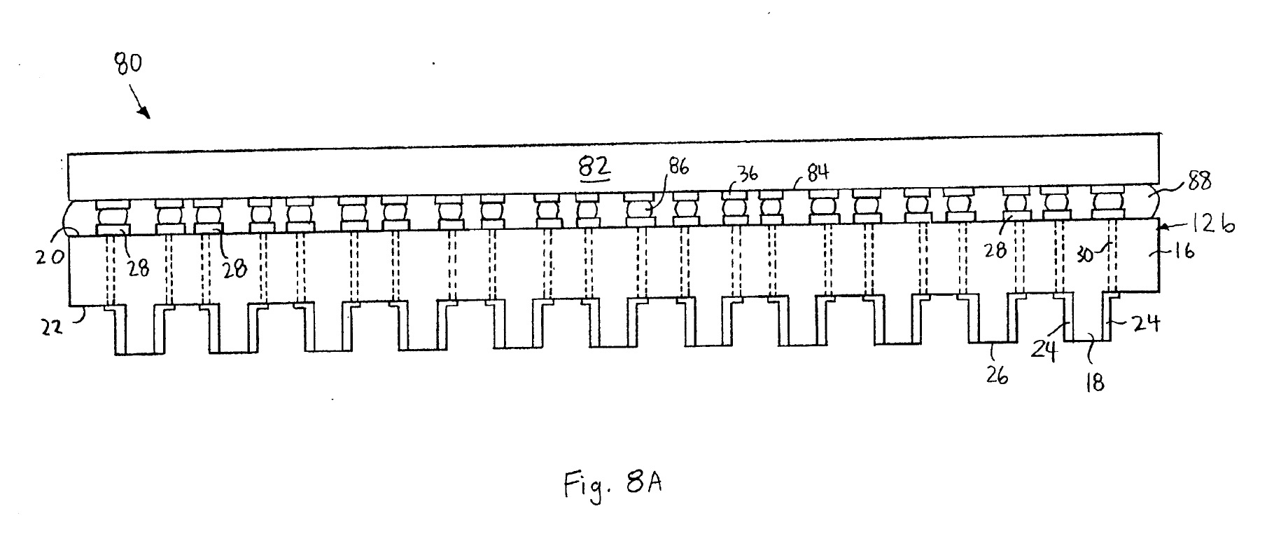

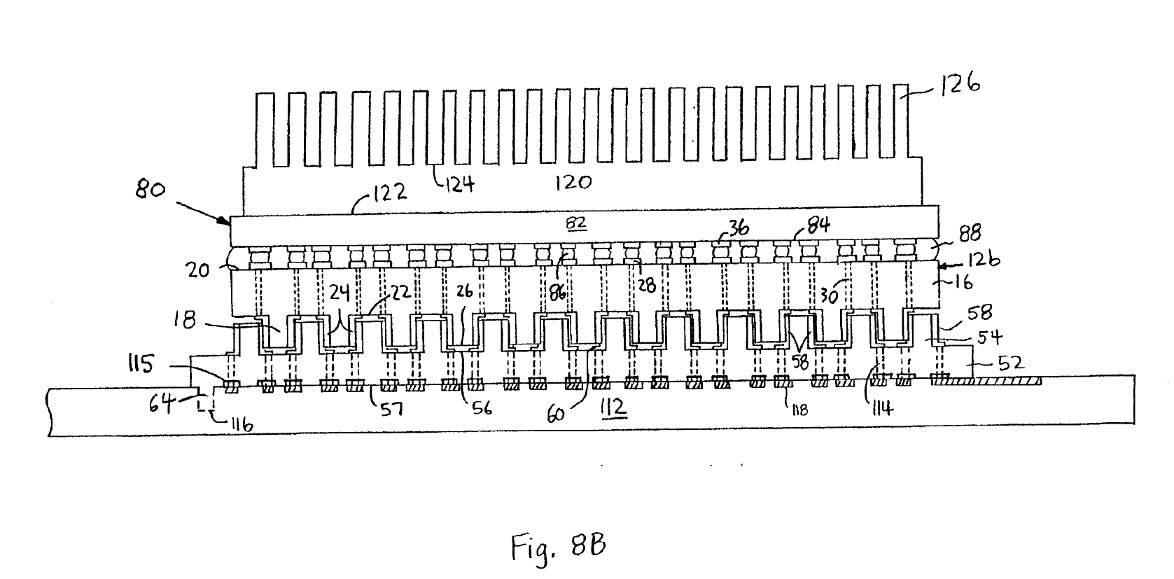

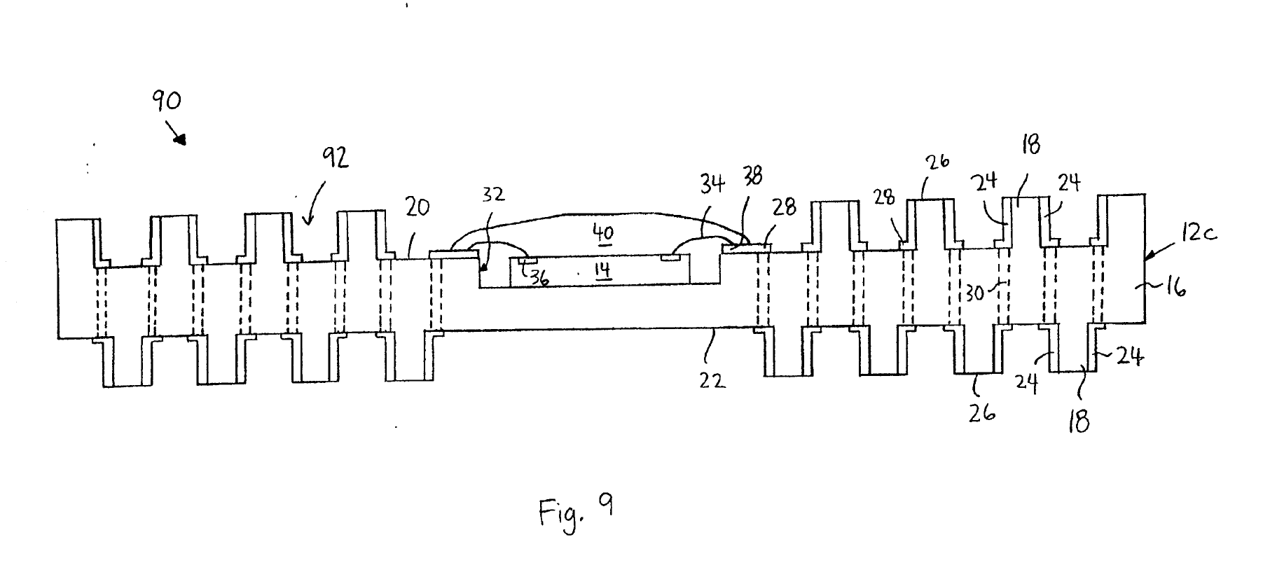

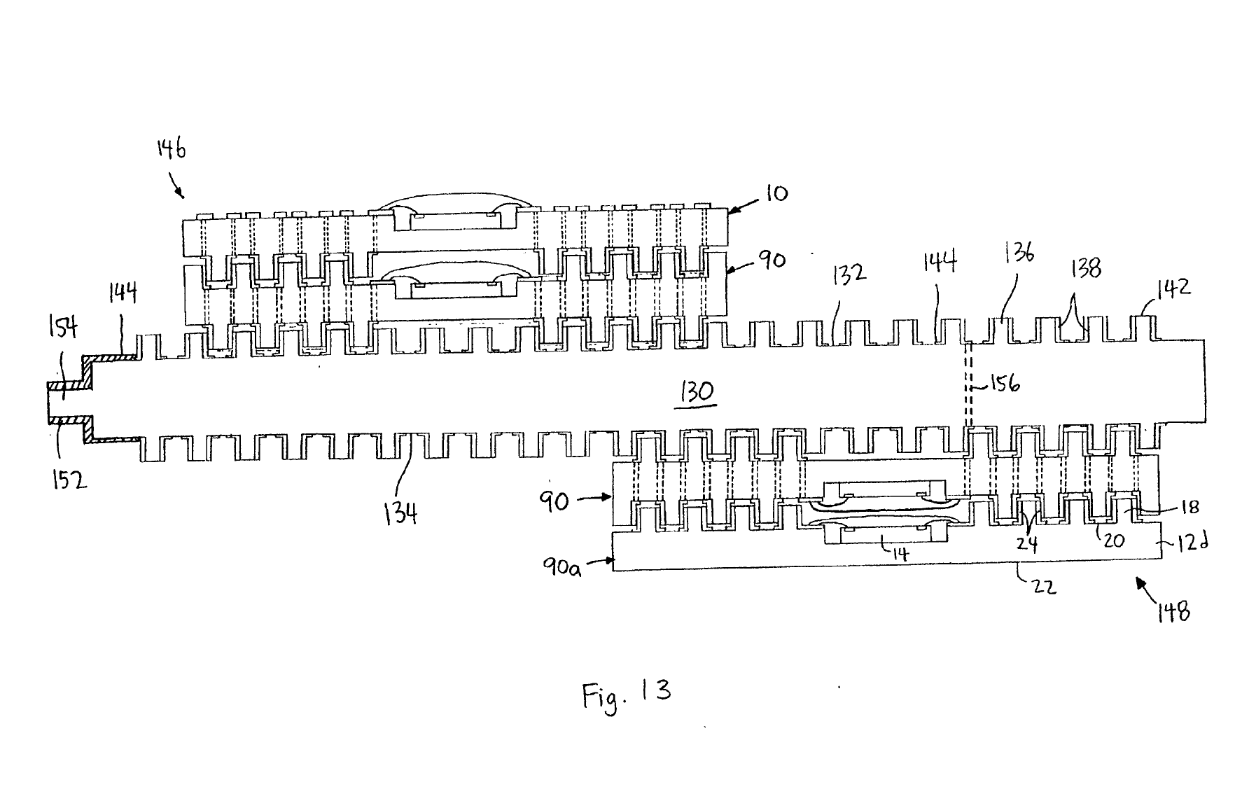

Figure 4 is a cross-sectional side view of an assembly 50 including integrated circuit package 10 of Figure 1 mounted on a mounting substrate 52. Mounting substrate 52 may be, for example, a socket mounted on a printed circuit board (see Figure 8B) or a structure that supports a plurality of packages and has an edge connector that provides electrical connection to external circuitry (see Figure 13).

In Figure 4, mounting substrate 52 includes a planar or substantially planar molded plastic body 53 and a plurality of integral plastic posts 54, which extend from an upper side 56 of body 53 and are substantially similar to posts 18 of package 10 of Figure 1. Four electrically separate metal terminals 58 are coated on and equally spaced on the exterior sidewall of each post 54 on mounting substrate 52. Each metal terminal 58 is electrically coupled to a conductive trace 60 on upper side 56 of mounting substrate 52. Like substrate 12 of package 10 of Figuremounting substrate 52 may be formed by injection molding of LCP or some other plastic material, and subsequently applying and patterning a metal coating (or coatings) thereon.

Although not shown in the view of Figure 4, traces 60 may extend laterally on upper side 56 to vias (not shown) extending through mounting substrate 52 to input/output terminals (not shown) on an opposite lower side 57 (see, e.g., Figure 8B). Alternatively, traces 60 may extend laterally on upper side 56 to a periphery of mounting substrate 52, where a connector (not shown) may include input/output terminals to enable external electrical connection of mounting substrate 52 (see, e.g., Figure 13).

To mount integrated circuit package 10 on mounting substrate 52 in Figure 4, posts 18 of package 10 are snugly wedged between adjacent posts 54 on mounting substrate 52. A tight engagement between posts 18 of package 10 and posts 54 of mounting substrate 52 is enabled by precisely controlling the diameter, location, and spacing of each post 18 of package 10 and each post 54 of mounting substrate 52.

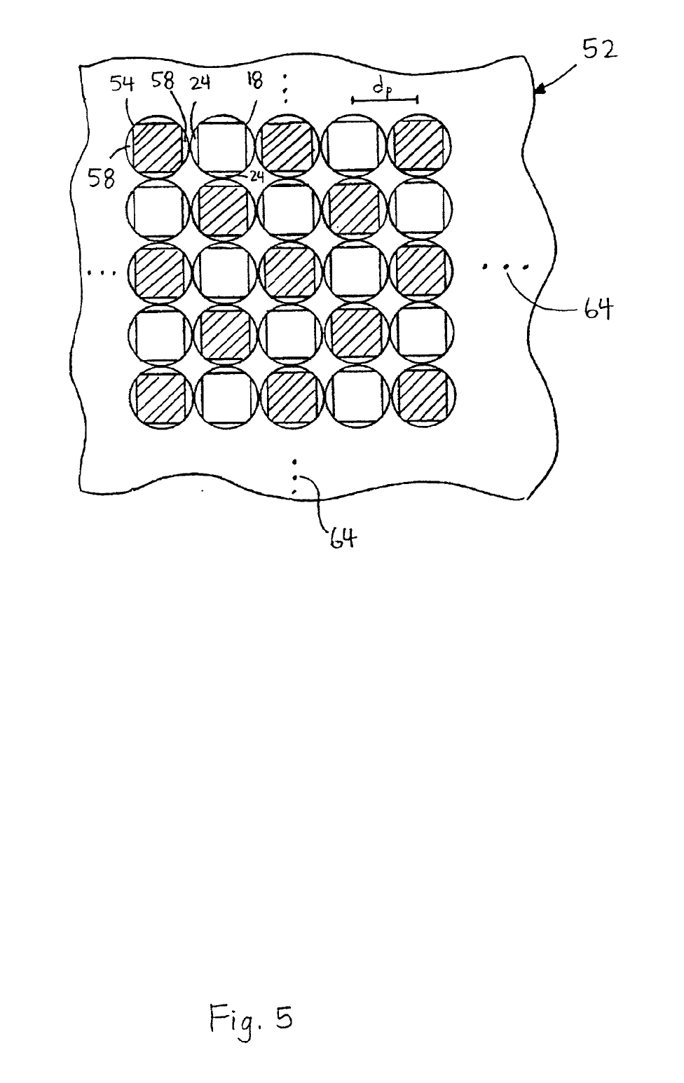

Figure 5 is a plan view of a portion of assembly 50 of Figure 4 through the line 5-5. Figure 5 shows the interlocking spatial relationship between posts 18 of package 10 and posts 54 of mounting substrate 52. Dots 64 represent additional posts 18 and posts 54 not shown. The center-to-center spacing between adjacent posts 18 and 54 is the diameter of one post 18 (or one post 54), dₚ. Each of the four metal terminals 24 on each post 18 of package 10 contacts a respective metal terminal 58 on one of the four nearest posts 54 of mounting substrate 52. The frictional metal-to-metal contact between metal terminals 24 on posts 18 of package 10 and metal terminals 58 on posts 54 of mounting substrate 52 provides an electrical and physical connection between package 10 and mounting substrate 52. In this manner, integrated circuit 14 of package 10 can communicate with external circuitry through traces 60 on mounting substrate 52 (see Figure 4). The electrical connection between package 10 and mounting substrate 52 can be broken simply by pulling package 10 from mounting substrate 52.

Alternatively, metal terminals 58 on posts 54 of mounting substrate 52 may include an outermost solder layer, which can be reflowed after posts 18 of package 10 are engaged with posts 54 of mounting substrate 52, thereby permanently joining package 10 to mounting substrate 52.

In the embodiment of Figure 4, the ends 62 of posts 54 of mounting substrate 52 do not contact lower side 22 of package 10, and the ends 26 of posts 18 of package 10 do not contact upper side 56 of mounting substrate 52. This avoids short-circuiting of metal terminals 58 on posts 54 of mounting substrate 52 to any conductive traces on lower side 22 of package 10, or short-circuiting of metal terminals 24 on posts 18 of package 10 to any conductive traces 60 on upper side 56 of mounting substrate 52. In an alternative embodiment, any conductive traces on lower side 22 of package 10 (and conductive traces 60 on upper side 56 of mounting substrate 52) may be sufficiently spaced, or covered by an insulative material. This would prevent short-circuiting in the event of contact between ends 62 of posts 54 and lower side 22 of package 10, or between ends 26 of posts 18 and upper side 56 of mounting substrate 52.

As shown in Figure 4, the exterior sidewalls of posts 18 of package 10 and the exterior sidewalls of posts 54 of mounting substrate 52 are orthogonal to sides 22 and 56, respectively. Alternatively, a small draft may be incorporated into the exterior sidewalls of posts 18, and into the exterior sidewalls of posts 54, to form tighter, albeit still non-permanent, connections between package 10 and mounting substrate 52. For example, the diameters of the exterior sidewalls of posts 18 of package 10 may be slightly smaller at lower side 22 than at ends 26. And, the diameters of the exterior sidewalls of posts 54 of mounting substrate 52 may be slightly smaller at upper side 56 than at ends 62. This provides an even tighter connection, since posts 18 of package 10 must be snapped between posts 54 of mounting substrate 52.

As mentioned briefly above, the number and arrangement of posts 18 of package 10 can vary. This would necessitate a corresponding variation in posts 54 of the mounting substrate 52 to which package 10 is attached. In addition, the geometry of posts 18 of package 10 and posts 54 of mounting substrate 52 can vary. The post geometry may vary, for example, in response to the number of input/output terminals needed on package 10 to accommodate the particular integrated circuit 14.

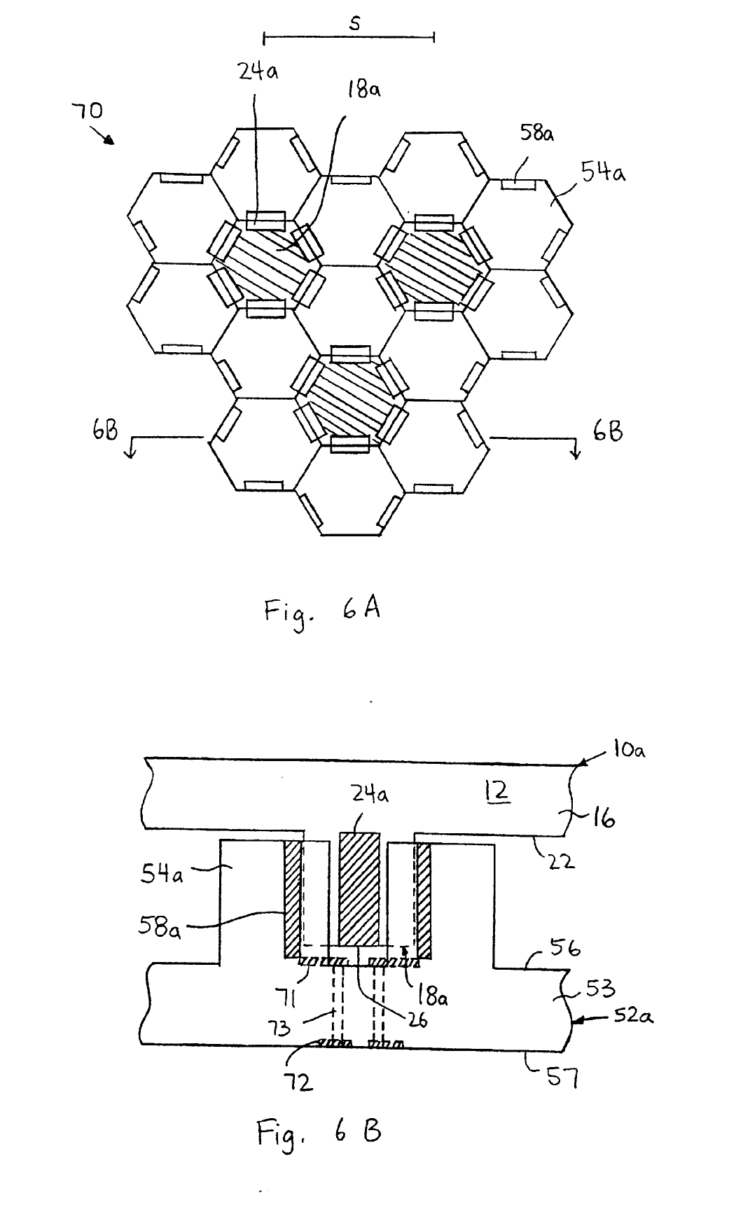

Figure 6A is a plan view of a post geometry 70 in accordance with an alternative embodiment of the present invention. Figure 6B is a cross-sectional side view of post geometry 70 of Figure 6A through the line 6B-6B. In post geometry 70, each of a plurality of posts 18a, extending from lower side 22 of body 16 of substrate 12 of an integrated circuit package 10a, has a hexagonal shape. The spacing between posts 18a may be s = 0.5 mm. Six electrically separate metal terminals 24a each extend from the surface of lower side 22, along the exterior sidewall of a face of a respective hexagonal post 18a, to end 26 of post 18a. Each metal terminal 24a may extend partly onto the surface of end 26 of the respective post 18a.

In post geometry 70, a plurality of posts 54a on upper side 56 of body 53 of mounting substrate 52a also each have a hexagonal shape and are arranged in a honeycomb pattern. Six hexagonal posts 54a border each opening where a post 18a of package 10a is to be inserted. Metal terminals 58a extend along the exterior faces of the six hexagonal posts 54a that face a respective post 18a. Since each post 54a of body 53 of mounting substrate 52a borders three posts 18a of package 10a, each post 54a includes three metal terminals 58a on alternating faces of the post 54a.

Once a package 10a is mounted on mounting substrate 52a, metal terminals 24a on posts 18a of package 10a contact respective metal terminals 58a on posts 54a of mounting substrate 52a. Ends 26 of posts 18a of package 10a do not touch upper side 56 of body 53 of mounting substrate 52a, as seen in Figure 6B. In the space below ends 26 of posts 18a, metal terminals 58a are each electrically coupled to a conductive trace 71 on upper side 56 in the openings where posts 18a are inserted. Each trace 71 is electrically coupled to a conductive trace 72 on a lower side 57 of mounting substrate 52a by a metal-coated via 73, which extends through mounting substrate 52a. This enables communication between integrated circuit 14 and external circuitry.

In an alternative embodiment, metal terminals 24a and posts 18a are actually provided on body 53 of mounting substrate 52a, while metal terminals 58a and posts 54a are actually provided on lower side 22 of body 16 of substrate 12 of package 10a. Such an embodiment provides more space on upper side 56 of body 53 of mounting substrate 52a for routing of conductive traces 71 for interconnection to external circuitry.

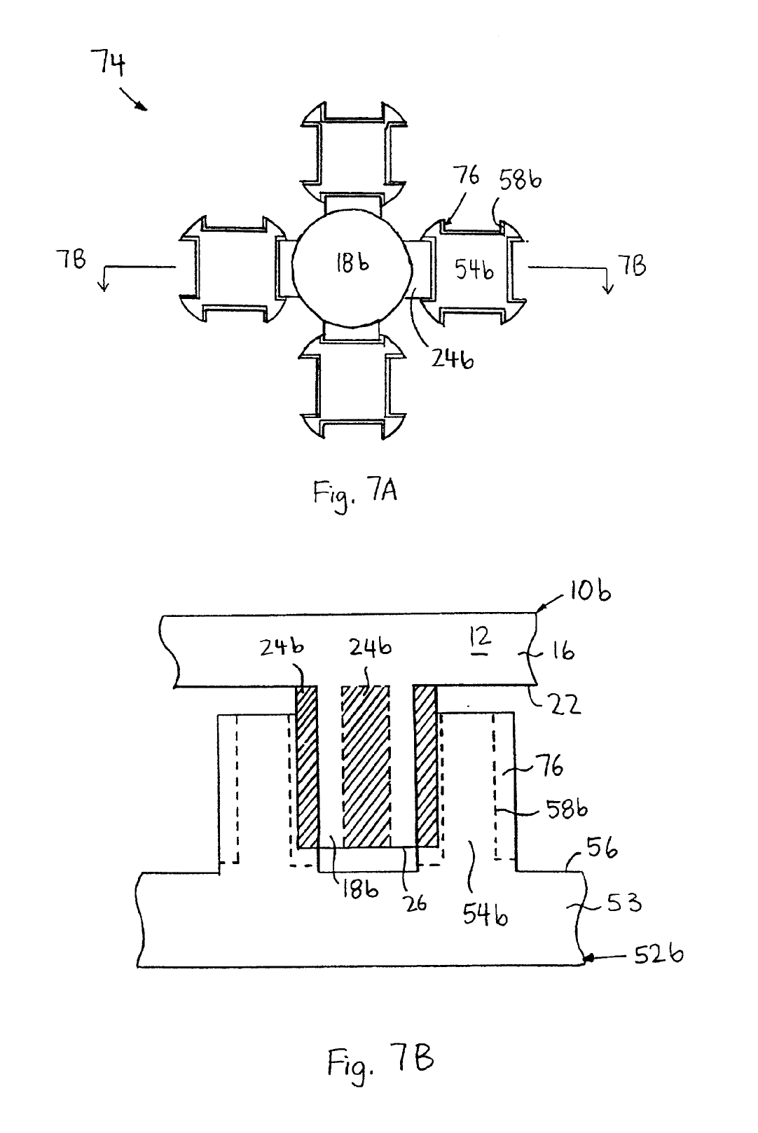

Figure 7A is a plan view of a post geometry 74 in accordance with an alternative embodiment of the present invention. Figure 7B is a cross-sectional side view of post geometry 74 of Figure 7A through the line 7B-7B. In post geometry 74, each of a plurality of posts 18b, extending from lower side 22 of body 16 of substrate 12 of an integrated circuit package 10b, has a cylindrical shape. Four electrically separate metal terminals 24b are equally spaced from each other and extend from the surface of lower side 22, along the exterior sidewall of a respective post 18b, to end 26 of post 18b. Each metal terminal 24b may extend partly onto the surface of end 26 of the respective post 18b.

As seen in Figure 7A, metal terminals 24b have a rectangular shape away from the sidewall of a respective post 18b. This may be accomplished by forming thick metal terminals 24b on posts 18b. Alternatively, posts 18b each may be shaped (e.g., molded) with a substantially cylindrical center with four, integral substantially rectangular protrusions extending from the exterior sidewall. Each metal terminal 24b could then be formed coating the surfaces of a respective rectangular protrusion.

In post geometry 74, a plurality of posts 54b on upper side 56 of body 53 of alternative mounting substrate 52b each have a complementary shape to posts 18b of package 10b. Four posts 54b border each opening where a post 18b of package 10b is to be inserted. Each post 54b of body 53 of mounting substrate 52b has a substantially cylindrical shape with four notches 76 formed equally spaced from each other in the exterior sidewall of post 54b. A metal terminal 58b lines each notch 76.

Notches 76 are oriented so that metal terminals 58b of posts 54b of body 53 of mounting substrate 52b face and contact respective metal terminals 24b on posts 18b of body 16 of substrate 12 of package 10b, once a package 10b is mounted on mounting substrate 52b. This enables communication between integrated circuit 14 and external circuitry.

In an alternative embodiment, the protrusions extending from posts 18b of body 16 of substrate 12 of package 10b may have a triangular shape, or another polygonal shape. In such embodiments, notches 76 in posts 54b of body 53 of mounting substrate 52b would have a complementary shape to facilitate interlocking with the protrusions of posts 18b of body 16 of substrate 12 of package 10b.

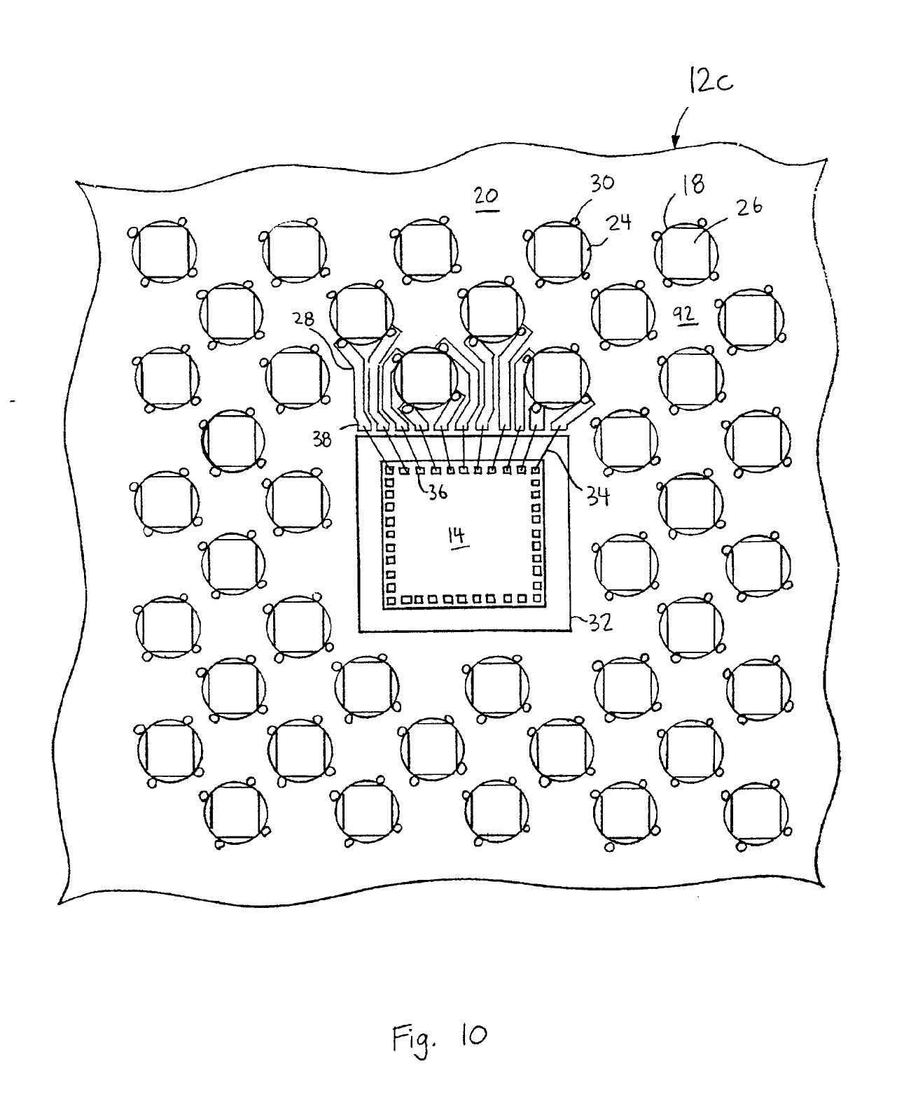

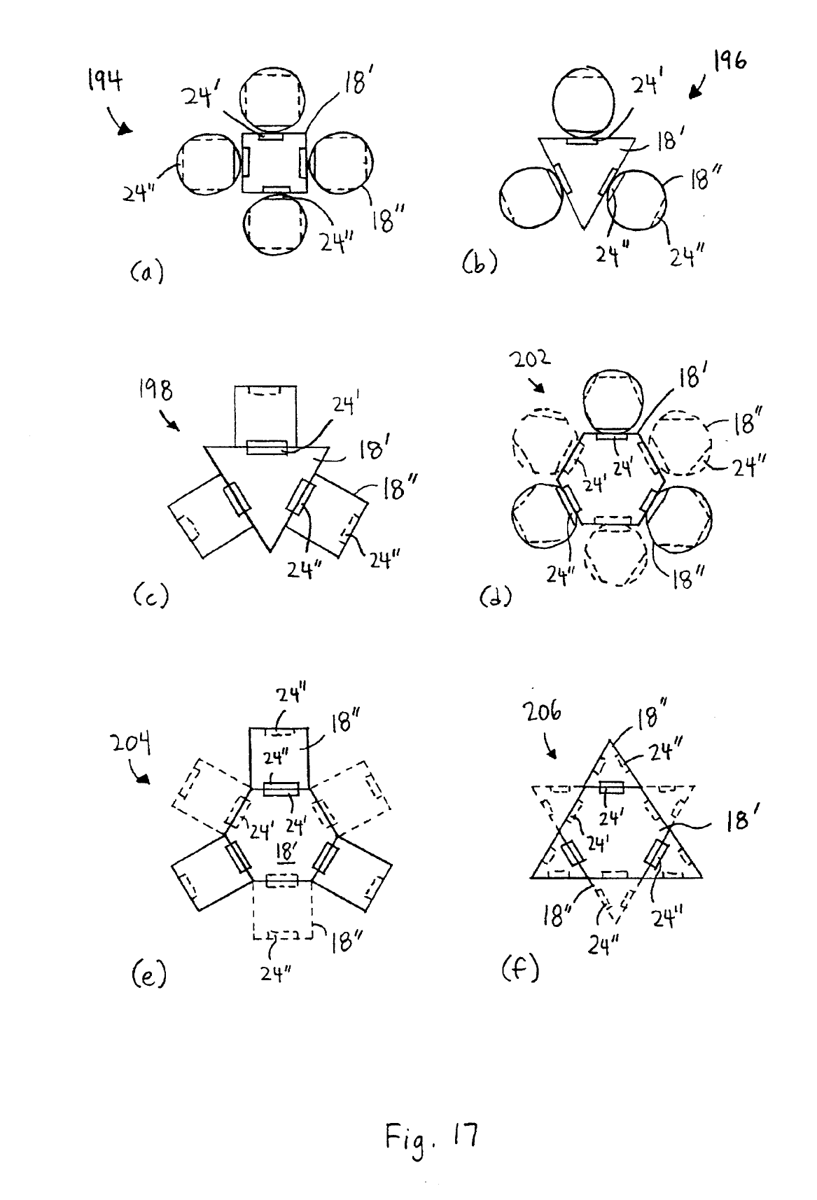

Figure 16 shows plan views of post geometries in accordance with alternative embodiments of the present invention. In Figure 16(a) through Figure 16(g), posts 18" and 18"" and metal terminals 24" and 24"" are similar to posts 18 and metal terminals 24, respectively, as described above with reference to package 10 of Figure 1. Posts 18", including metal terminals 24", may be part of a substrate of an integrated circuit package (e.g., similar to substrate 12 of package 10 of Figure 1), or they may be part of a mounting substrate similar to mounting substrate 54 of Figure 4. Similarly, posts 18"", including metal terminals 24"", may be part of a substrate of an integrated circuit package or part of a mounting substrate. In the discussions of Figure 16(a) through Figure 16(g), an "IC package assembly" refers to a single integrated circuit package mounted on a mounting substrate, or to a stack of two or more integrated circuit packages, where the stack itself may be mounted on a mounting substrate. See, for example, the discussion of stacked packages in Figure 9 through Figure 12 below.

In Figure 16(a), an isolated line 182 of one post 18" in between two posts 18"" is shown. Two metal terminals 24" on post 18" are each electrically coupled to one respective metal terminal 24"" on each post 18"". An IC package assembly may be physically and electrically coupled together using a plurality of isolated lines 182 spaced from each other. Alternatively, as shown in Figure 16(b), a plurality of posts 18" and 18"", spatially related as shown in Figure 16(a), may be arranged in a larger interlocking spatial relationship similar to that shown in Figure 5. In Figure 16(b), two metal terminals 24" (or 24"") are equally spaced on the sidewall of each post 18" (or 18"").

In Figure 16(c), a cluster 184 of one post 18" centered between three equally spaced posts 18"" is shown. Three metal terminals 24" on post 18" are each electrically coupled to one respective metal terminal 24"" on each post 18"". An IC package assembly may be physically and electrically coupled together using a plurality of clusters 184 spaced from each other. Alternatively, as shown in Figure 16(d), a plurality of posts 18" and 18"", spatially related as shown in Figure 16(c), may be arranged in a larger interlocking spatial relationship similar to that shown in Figure 5. In Figure 16(d), three metal terminals 24" (or 24"") are equally spaced on the sidewall of each post 18" (or 18"").

In Figure 16(e), a cluster 186 of one post 18" centered between four equally spaced posts 18"" is shown. Four metal terminals 24" on post 18" are each electrically coupled to one respective metal terminal 24"" on each post 18"". An IC package assembly may be physically and electrically coupled together using a plurality of clusters 186 spaced from each other. Alternatively, a plurality of posts 18" and 18"", spatially related as shown in Figure 16(e), may be arranged in a larger interlocking spatial relationship yielding the arrangement shown in Figure In such a case, four metal terminals 24" (or 24"") would be equally spaced on the sidewall of each post 18" (or 18"").

In Figure 16(f), a cluster 188 is similar to cluster 184 of Figure 16(c). Unlike cluster 184, however, post 18" of cluster 188 is larger in diameter than posts 18"". In Figure 16(g), a cluster 192 is similar to cluster 186 of Figure 16(e). Unlike cluster 186, however, post 18" of cluster 192 is larger in diameter than posts 18"". A plurality of spaced clusters 188 of Figure 16(f), or spaced clusters 192 of Figure 16(g), may be used to couple, physically and electrically, an IC package assembly. Alternatively, as indicated by the dashed metal terminals 24"", a plurality of posts 18" and 18"", spatially related as shown in Figure 16(f) or Figure 16(g), may be arranged into a larger interlocking arrangement similar to that shown in Figure 5.

With respect to the variations of Figures 16(a) to 16(g), artisans will appreciate that a more snug frictional interconnection of the posts 18" and 18"" will typically be provided where more of the posts 18" and 18"" are engaged.

Figure 17 shows plan views of post geometries in accordance with alternative embodiments of the present invention. In Figure 17(a) through Figure 17(f), posts 18" and 18"" and metal terminals 24" and 24"" are similar to posts 18 and metal terminals 24, respectively, as described above with reference to package 10 of Figure 1. Posts 18", including metal terminals 24", may be part of a substrate of an integrated circuit package (e.g., similar to substrate 12 of package 10 of Figure 1), or they may be part of a mounting substrate similar to mounting substrate 54 of Figure 4. Similarly, posts 18"", including metal terminals 24"", may be part of a substrate of an integrated circuit package or part of a mounting substrate. In the discussions of Figure 17(a) through Figure 17(f), an "IC package assembly" refers to a single integrated circuit package mounted on a mounting substrate, or to a stack of two or more integrated circuit packages, where the stack itself may be mounted on a mounting substrate. See, for example, the discussion of stacked packages in Figure 9 through Figure 12 below.

In Figure 17(a), a cluster 194 of one post 18" centered between four equally spaced posts 18"" is shown. Post 18" has a square plan cross-section, and posts 18"" have circular plan cross-sections. Four metal terminals 24" on post 18" are each electrically coupled to one respective metal terminal 24"" on each post 18"".

In Figure 17(b), a cluster 196 of one post 18" centered between three equally spaced posts 18"" is shown. Post 18" has a triangular plan cross-section, and posts 18"" have circular plan cross-sections. Three metal terminals 24" on post 18" are each electrically coupled to one respective metal terminal 24"" on each post 18"".

In Figure 17(c), a cluster 198 of one post 18" centered between three equally spaced posts 18"" is shown. Post 18" has a triangular plan cross-section, and posts 18"" have square plan cross-sections. Three metal terminals 24" on post 18" are each electrically coupled to one respective metal terminal 24"" on each post 18"".

In Figure 17(d), a cluster 202 of one post 18" centered between three (or six) equally spaced posts 18"" is shown. Post 18" has a hexagonal plan cross-section, and posts 18"" have circular plan cross-sections. Three (or six) metal terminals 24" on post 18" are each electrically coupled to one respective metal terminal 24"" on each post 18"".

In Figure 17(e), a cluster 204 of one post 18" centered between three (or six) equally spaced posts 18"" is shown. Post 18" has a hexagonal plan cross-section, and posts 18"" have square plan cross-sections. Three (or six) metal terminals 24" on post 18" are each electrically coupled to one respective metal terminal 24"" on each post 18"".

In Figure 17(f), a cluster 206 of one post 18" centered between three (or six) equally spaced posts 18"" is shown. Post 18" has a hexagonal plan cross-section, and posts 18"" have triangular plan cross-sections. Three (or six) metal terminals 24" on post 18" are each electrically coupled to one respective metal terminal 24"" on each post 18"".

An IC package assembly may be physically and electrically coupled together using a plurality of clusters 194, 196, 198, 202, 204, or 206, of Figure 17(a) through Figure 17(f) respectively, that are spaced from one another. Alternatively, as indicated by the dashed metal terminals 24"", a plurality of posts 18" and 18"", spatially related as shown in the respective figures, may be arranged into a larger interlocking arrangement similar to that shown in Figure 5.

Artisans will appreciate that post geometries other than those shown in Figure 6A, Figure 7A, Figure 16(a) through Figure 16(g), and Figure 17(a) through Figure 17(f) are possible. Further, within the various post geometries, the relative sizes of the posts may vary.

Figure 8A is a cross-sectional side view of an integrated circuit package 80 in accordance with an alternative embodiment of the present invention. Package 80 of Figure 8A is similar to package 10 of Figure 1, and some features of package 80 have the same reference numbers as similar features of package 10. Accordingly, to avoid redundancy, our discussion will focus on differences between package 80 and package 10.

Package 80 of Figure 8A includes an integrated circuit mounted in a flip chip configuration on a substrate 12b. The integrated circuit is denoted as flip chip 82, which may be, for example, a microprocessor chip. Flip chip 82 is mounted on upper side 20 of body 16, which in this case is planar and lacks recess 32 of body 16 of package 10 of Figure 1. Flip chip 82 is mounted with an active first surface 84, which includes conductive bond pads 36, facing upper side 20 of body 16, so that flip chip 82 is electrically coupled to traces 28 on upper side 20 of body 16. Each of a plurality of conductive balls 86 (e.g., lead tin solder balls) electrically couples a respective conductive bond pad 36 of flip chip 82 to a respective trace 28.

In Figure 8A, upper side 20 of substrate 12b has the same area, or approximately the same area, as active first surface 84 of flip chip 82, thus achieving a small footprint package. In some embodiments, substrate 12b of package 80 of Figure 8A may extend beyond the lateral edges of flip chip 82. In such a case, conductive bumps 86 may electrically couple bond pads 36 of flip chip 82 to corresponding metal lands at first ends of traces 28 on upper side 20 of body 16. Traces 28 may then extend along upper side 20 of body 16, beyond the edges of flip chip 82, to second ends, which are each electrically coupled to respective vias 30.

In Figure 8A, an optional electrically insulative, adhesive underfill material 88 is present around flip chip 82 between active first surface 84 of flip chip 82 and upper side 20 of body 16 of substrate 12b. Additionally, or alternatively, a glob of encapsulant (not shown) may be applied over flip chip 82.

Similarly to package 10 of Figuremetal-coated vias 30 extend from traces 28, through body 16 of substrate 12b of package 80, to metal terminals 24 on the sidewalls of posts 18, which extend from lower side 22 of body 16 of substrate 12b. Unlike in substrate 12 of package 10 of Figure 1, posts 18 of substrate 12b of package 80 are located over the entire area of lower side 22 of body 16. This configuration provides maximum use of available space on lower side 22 and allows the footprint of package 80 to be minimized. Package 80 of Figure 8A may be then be mounted on mounting substrate 52, similar to package 10 of Figure 1 as shown in Figure 4.

Figure 8B is a cross-sectional side view of integrated circuit package 80 of Figure 8A mounted on a mounting substrate 52, which is mounted on a printed circuit board 112. Each post 18 on lower side 22 of package 80 is snugly wedged between adjacent posts 54 on mounting substrate 52, as discussed above with reference to Figure 4. Each of the four metal terminals 24 on each post 18 on lower side 22 of package 80 contacts a respective metal terminal 58 on one of the four nearest posts 54 of mounting substrate 52. Each metal terminal 58 on posts 54 of mounting substrate 52 is, in turn, coupled to a respective conductive trace 60 on upper side 56 of mounting substrate 52, through which an electrical connection to external circuitry is made.

In the embodiment of Figure 8B, mounting substrate 52 includes a plurality of metal-coated vias 114, each electrically coupled at a first end to a respective trace 60 and extending through mounting substrate 52 to a second end at lower side 57 of mounting substrate 52. Second ends of vias 114 are electrically coupled to respective ones of a plurality of input/output terminals (e.g., metal lands 115, or alternatively, metal pins or solder balls) on lower side 57. Mounting substrate 52 is mounted on printed circuit board 112 so that the input/output terminals of mounting substrate 52 are electrically coupled (e.g., soldered) to conductive traces 118 of printed circuit board 112. In this manner, flip chip 82 of package 80 can communicate with external circuitry through traces 60, vias 114, and the input/output terminals of mounting substrate 52, and traces 118 of printed circuit board 112. The electrical connection between package 80 and mounting substrate 52 can be broken simply by pulling package 80 from mounting substrate 52.

Alternatively, mounting substrate 52 can be mounted on printed circuit board 112 using a clamp to maintain the physical connection.

In the embodiment of Figure 8B, mounting substrate 52 also includes an optional projection 64 extending from lower side 57 near the periphery of mounting substrate 52. Projection 64 fits into a complementary hole 116 in the upper surface of printed circuit board 112 to aid alignment of mounting substrate 52 on printed circuit board 112. Alternatively, a plurality of such projections 64 and complementary holes 116 may be used.

A heat sink 120 is also shown in Figure 8B mounted on top of package 80. Heat sink 120 includes a first surface 122 and an opposite second surface 124. First surface 122 of heat sink 120 is attached to an exposed surface of flip chip 82 of package 80 using, for example, a thermally conductive adhesive. A plurality of fins 126 extends vertically from second surface 124 of heat sink 120. Heat sink 120, including fins 126, may be formed (e.g., machined) of metal, such as aluminum or copper. Heat sink 120 increases the heat dissipation capability of flip chip 82 of package 80. This may be especially important if flip chip 82 is a microprocessor with significant heat generation.

Figure 9 is a cross-sectional side view of a stackable integrated circuit package 90 in accordance with an alternative embodiment of the present invention. Package 90 of Figure 9 is similar to package 10 of Figure 1, and some features of package 90 have the same reference numbers as similar features of package 10. Accordingly, to avoid redundancy, our discussion will focus on differences between package 90 and package 10. Like substrate 12 of package 10 of Figure 1, package 90 of Figure 9 includes a substrate 12c including four electrically separate metal terminals 24 coating the sidewall of each post 18 extending from lower side 22 of body 16.

Unlike package 10, however, package 90 includes a plurality of posts 18 extending from upper side 20 of body 16. Four electrically separate metal terminals 24 are equally spaced on the exterior sidewall of each post 18. Each metal terminal 24 coats a portion of the sidewall of a respective post 18. Metal terminals 24 each extend from the surface of upper side 20, along the exterior sidewall of a respective post 18 on upper side 20, to an end 26 of post 18. Each metal terminal 24 may extend partly onto the surface of end 26 of the respective post 18 on upper side 20.

Each of the four metal terminals 24 on a post 18 on upper side 20 is electrically coupled by a respective via 30 to one metal terminal 24 on one of the four nearest posts 18 on lower side 22 of body 16. In addition, bond pads 36 on integrated circuit 14 are electrically coupled to respective metal terminals 24 on posts 18 on upper side 20 of body 16, through respective bond wires 34, leadfingers 38, and traces 28 on upper side 20. Thus, each bond pad 36 of integrated circuit 14 is electrically coupled to a respective metal terminal 24 on a post 18 on upper side 20 of body 16 and to a respective metal terminal 24 on a post 18 on lower side 22 of body 16.

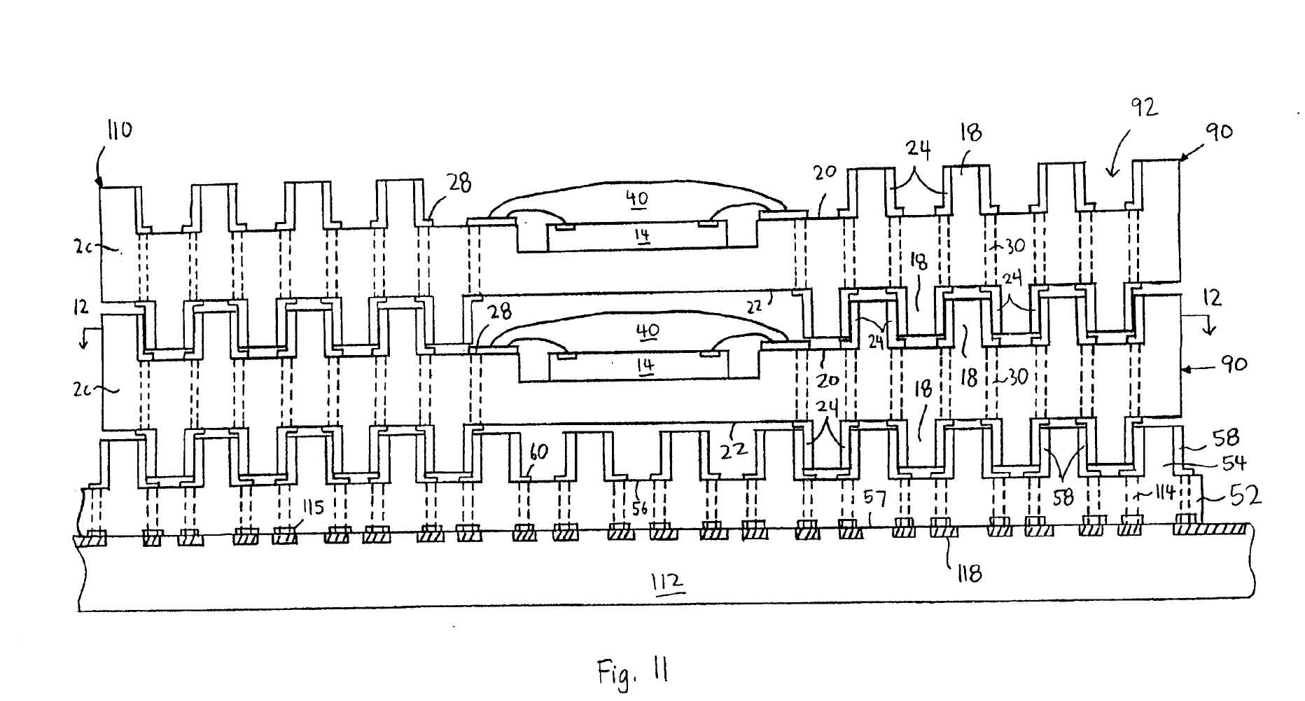

Figure 10 is a plan view of a portion of upper side 20 of body 16 of stackable integrated circuit package 90 of Figure 9. Figure 10 shows the arrangement of posts 18 on upper side 20. Each of the four metal terminals 24 on the sidewall of a respective post 18 is shown extending partly onto the surface of end 26 of the post 18. Four metal-coated vias 30 are adjacent to each post 18 and are electrically coupled to a respective metal terminal 24 of the post 18. Bond pads 36 on integrated circuit 14 are electrically coupled to leadfingers 38 of respective traces 28 by bond wires 34. The end of each trace 28, opposite to leadfinger 38, is coupled to a respective metal-coated via 30. Metal-coated vias 30 each extend through body 16 to lower side 22, eventually leading to a respective metal terminal 24 on a respective post 18 on lower side 22 of body 16. In the embodiment of Figure 10, only a representative sample of bond pads 36, bond wires 34, leadfingers 38, and traces 28 are shown.

Posts 18 on upper and lower sides 20 and 22 of package 90 of Figure 9 and Figure 10 have the same diameter. Posts 18 on upper side 20 of body 16 of package 90 are arranged in a complementary checkerboard pattern to the checkerboard pattern of posts 18 on lower side 22 of body 16. In other words, each post 18 on lower side 22 of body 16 is centrally aligned with a respective space 92 between posts 18 on upper side 20. In order to accommodate this post arrangement, vias 30 are shown abutting respective posts 18 near the peripheries of respective metal terminals 24. Alternatively, vias 30 may be spaced farther from posts 18 on upper and lower sides 20 and 22 and electrically coupled to two respective metal terminals 24 by conductive traces 28 on upper and lower sides 20 and 22.

The arrangement of posts 18 on lower side 22 of body 16 of package 90 is similar to the checkerboard arrangement of posts 18 on lower side 22 of body 16 of package 10, as shown in Figure 3. One difference, however, between lower side 22 of body 16 of package 10 and lower side 22 of body 16 of package 90 is the locations of vias 30. In package 10 of Figure 1 and Figure 3, vias 30 are shown aligned at the midpoints of metal terminals 24. In package 90 of Figure 9, vias 30 are displaced toward the peripheries of metal terminals 24, as seen in Figure 10.

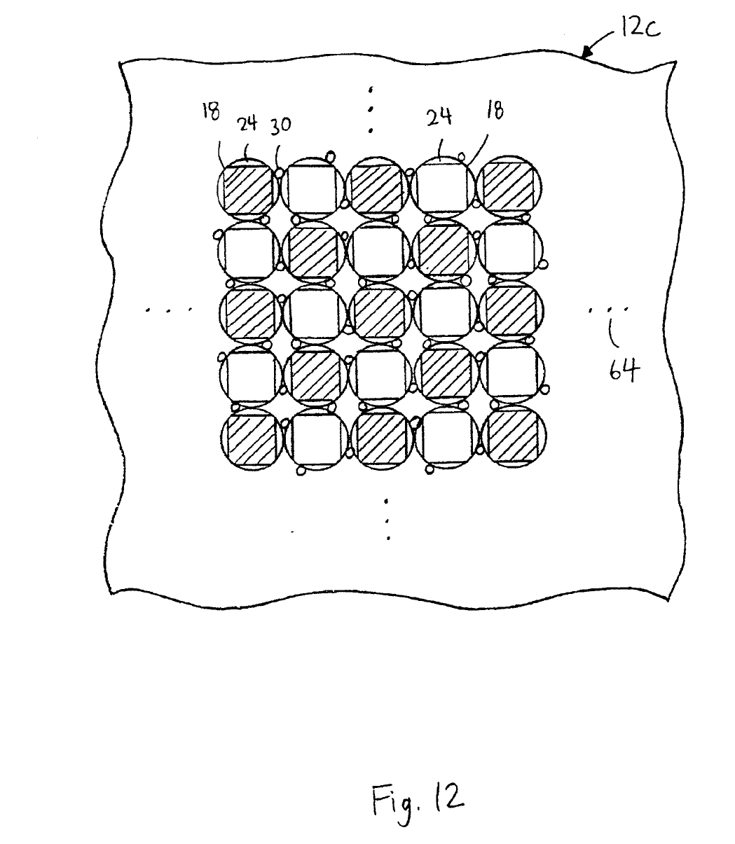

The arrangements of posts 18 on upper and lower sides 20 and 22 of body 16 described above enable stacking of multiple packages 90 of Figure 9. Figure 11 is a cross-sectional side view of a stack 110 including two packages 90 of Figure 9 stacked together and mounted on a mounting substrate 52, which is mounted on a printed circuit board 112. The two packages 90 are arranged one on top of the other and are physically and electrically coupled to each other. Posts 18 on lower side 22 of the top package 90 are snugly wedged between respective posts 18 on upper side 20 of the bottom package 90. The two packages 90 are thus electrically coupled in parallel, since each via 30 of the top package 90 is coupled to a respective one of the vias 30 of the bottom package 90.

Figure 12 is a plan view of a portion of stack 110 of Figure 11 through the line 12-12. Figure 12 shows the interlocking spatial relationship (i.e., interlocking checkerboard patterns) between posts 18 (hashed) on lower side 22 of the top package 90 and posts 18 (clear) on upper side 20 of the bottom package 90. Dots 64 represent additional posts 18 not shown. Each of the four metal terminals 24 on each post 18 on lower side 22 of the top package 90 contacts a respective one of the metal terminals 24 on one of the four nearest posts 18 on upper side 20 of the bottom package 90. Each via 30 is shown contacting the peripheral regions of two respective metal terminals 24 of two adjacent posts 18, one from each package 90. The frictional metal-to-metal contact between metal terminals 24 of posts 18 (on lower side 22) of top package 90 and metal terminals 24 of posts 18 (on upper side 20) of bottom package 90 provides an electrical and physical connection between the two packages 90. As discussed above, the electrical connection between the two packages 90 can be broken simply by pulling the top package 90 from the bottom package 90.

Returning to Figure 11, each post 18 on lower side 22 of the bottom package 90 is snugly wedged between adjacent posts 54 on mounting substrate 52, as discussed above with reference to Figure 4 and Figure 8B. Each of the four metal terminals 24 on each post 18 on lower side 22 of the bottom package 90 contacts a respective metal terminal 58 on one of the four nearest posts 54 of mounting substrate 52. Each metal terminal 58 on posts 54 of mounting substrate 52 is, in turn, coupled to a respective conductive trace 60 on upper side 56 of mounting substrate 52.

Similarly to the embodiment of Figure 8B, in the embodiment of Figure 11, mounting substrate 52 includes a plurality of metal-coated vias 114. Each via 114 is electrically coupled at a first end to a respective trace 60 and extends through mounting substrate 52 to a second end at lower side 57 of mounting substrate 52. Second ends of vias 114 are electrically coupled to respective ones of a plurality of input/output terminals (e.g., metal lands 115, or alternatively, metal pins or solder balls) on lower side 57. Mounting substrate 52 is mounted on printed circuit board 112 so that the input/output terminals of mounting substrate 52 are electrically coupled to conductive traces 118 of printed circuit board 112. In this manner, integrated circuits 14 of packages 90 can communicate with external circuitry through traces 60, vias 114, and the input/output terminals of mounting substrate 52, and traces 118 of printed circuit board 112. The electrical connection between the bottom package 90 and mounting substrate 52 can be broken simply by pulling package 90 from mounting substrate 52.

In the embodiment of Figure 11, the two packages 90 are arranged with the integrated circuits 14 of each package in stack 110 facing away from mounting substrate 52. Since the configurations of posts 18 on upper and lower sides 20 and 22 of package 90 are similar to each other, in an alternative embodiment, packages 90 may be oriented so that integrated circuits 14 are facing mounting substrate 52. In such an embodiment, posts 18 of upper side 20 of the bottommost package 90 are engaged with posts 54 on upper side 56 of mounting substrate 52.In the embodiment of Figure 11, the two integrated circuits 14 may each be, for example, a memory device, such as a DRAM, SRAM, or flash memory device. Accordingly, the overall size of the memory could be increased by stacking additional packages 90 on top of the two packages 90 shown stacked in Figure 11.

In an alternative embodiment, packages with differing types of integrated circuits 14 (e.g., a memory device and a microprocessor), but similar substrates 12c, could be stacked one on top of the other. The two packages might have different post counts, with the smaller post count package (e.g., a memory) stacked on top of the larger post count package (e.g., a microprocessor). The routing of traces 28 might be changed and additional conductive traces could be provided on lower side 22 of one or more of the packages to accommodate electrical interconnection of different integrated circuits 14.

In the routing scheme shown in Figure 11, each via 30 electrically couples two metal terminals 24 (each on respective posts 18 on upper and lower sides 20 and 22 of a respective package 90) that are vertically aligned with each other. In some embodiments, the two metal terminals 24 (of a respective package 90) coupled by a respective via 30 may not be vertically aligned. This could be accomplished by spacing such a via 30 a distance away from the two posts 18 on which the respective metal terminals 24 are located. One conductive trace 28 on upper side 20 of body 16 of package 90 would electrically couple one end of the via 30 to any metal terminal 24 on a post 18 on upper side 20 body 16. A second trace 28 on lower side 22 of body 16 of package 90 would electrically couple the other end of the via 30 to any metal terminal 24 on a post 18 on lower side 22 of body 16. Such a routing embodiment may be particularly useful in cases where integrated circuits 14 of the stacked packages 90 are not the same type of integrated circuit.

In some embodiments, one or more packages 90 may be stacked with one or more packages 10 of Figure 1, since the arrangement of posts 18 on lower side 22 of body 16 of package 10 is similar to that of package 90 of Figure 9.

As discussed with reference to package 10 of Figure 1, the number and arrangement of posts 18 of package 90 of Figure 9 can vary. The arrangement, however, must be designed so that posts 18 on upper side 20 and posts 18 on lower side 22 interlock when packages 90 (or package 90 and another package, such as package 10 of Figure 1) are stacked, for example, as shown in Figure 11.

Figure 13 is a cross-sectional side view of a plastic mounting substrate 130 that may be used (instead of mounting substrate 52 mounted on printed circuit board 112 of Figure 8B or Figure 11) for mounting packages disclosed herein in accordance with the present invention. Mounting substrate 130 includes an upper side 132, an opposite lower side 134, and a plurality of posts 136 extending vertically from both sides 132 and 134. Posts 136 are like posts 18 of package 10 of Figure 1, and like posts 54 of mounting substrate 52 of Figure 5, Figure 8B, and Figure 11. In particular, on the exterior sidewall of each post 136 are four equally spaced metal terminals 138, similar to metal terminals 24 of posts 18 of package 10 of Figure 1.

A first stack 146, including one package 10 of Figure 1 stacked on top of one package 90 of Figure 9, is mounted on upper side 132 of mounting substrate 130. A second stack 148, including a package 90a stacked on top of one package 90 of Figure 9, is mounted on lower side 134 of mounting substrate 130. Posts 18 on lower sides 22 of each of the two packages 90 of stacks 146 and 148 are engaged with posts 136 on upper and lower sides 132 and 134, respectively, of mounting substrate 130, as discussed above with reference to Figure 4 and Figure 5. The two integrated circuits 14 shown in the two packages in each of stacks 146 and 148 may be similar integrated circuits (e.g., memory chips), or they may be different integrated circuits (e.g., a microprocessor and a memory chip).

Package 90a in Figure 13 is similar to package 90 of Figure 9, but posts 18 on lower side 22 of substrate 12 of package 90 have been omitted on a substrate 12d of package 90a. Since package 90a includes posts 18 only on upper side 20, package 90a is oriented with integrated circuit 14 facing integrated circuit 14 of the package 90 to which package 90a is coupled. Posts 18 on upper side 20 of substrate 12d of package 90a face and engage posts 18 on upper side 20 of substrate 12 of package 90. Packages 90 and 90a are thus physically coupled together, as well as electrically coupled in parallel, since metal terminals 24 of each post 18 of package 90a are coupled to respective metal terminals 24 of posts 18 of package 90. Since package 90a does not include any posts 18 on lower side 22, package 90a must be the topmost package in the stack, or package 90a must be directly mounted on a mounting substrate, such as mounting substrate 130.

Metal terminals 138 of posts 136 of mounting substrate 130 are each electrically coupled to a first end of a respective one of a plurality of electrically conductive traces 144 on upper and lower sides 132 and 134 of mounting substrate 130. The opposite end of some or all of traces 144 may be electrically connected to a respective metal terminal 152 of an edge connector 154 of mounting substrate 130. Metal terminals 152 serve as input/output terminals for mounting substrate 130. Edge connector 154 may, in turn, be inserted into an interconnection receptacle on a motherboard or in an electronic chassis. In this manner, integrated circuits 14 of packages 10, 90, and 90a can communicate with external circuitry through metal terminals 152. Mounting substrate 130 may include a single edge connector 154 with one or more metal terminals 152. Alternatively, mounting substrate 130 may include a plurality of edge connectors 154, each with one or more metal terminals 152.

Alternatively, the opposite ends of some traces 144 may electrically connect to other metal terminals 138 on posts 136 on the same side of mounting substrate 130. Thus, packages, or stacks of packages, mounted on the same side (e.g., upper side 132 or lower side 134) of mounting substrate 130 may be interconnected. In addition, a plurality of metal-coated vias 156 may extend through mounting substrate 130 to electrically connect traces 144 on upper side 132 to traces 144 on lower side 134. In this manner, packages (or stacks of packages) mounted on upper side 132 of mounting substrate 130 may be electrically connected to packages (or stacks of packages) mounted on lower side 134 of mounting substrate 130. Accordingly, packages 10, 90, or 90a shown mounted on mounting substrate 130 in Figure 13 may be electrically connected to each other, and they may be electrically connected to external circuitry through edge connector 154.

When mounting substrate 130 of Figure 13 is used instead of mounting substrate 52 and printed circuit board 112 of Figure 8B or Figure 11, packages 10, 90, and 90a (or stacks thereof) may be directly mounted onto sides 132 and 134 of mounting substrate 130, as shown in Figure 13. Posts 18 of the bottom package of the stacks are engaged with posts 136 of mounting substrate 130. Thus, metal terminals 24 on posts 18 of the bottom packages are electrically coupled to respective metal terminals 138 on posts 136 of mounting substrate 130. Accordingly, there is no need for a soldered interconnection between mounting substrate 130 and packages 10, 90, or 90a mounted thereon. This gives the user maximum flexibility and convenience in mounting various, possibly stacked, packages on mounting substrate 130, and also provides the capability of easily removing and replacing the packages. Of course, an alternative embodiment may include coating metal terminals 24 on posts 18 of one or more of the packages with solder, and reflowing the solder after mounting the package(s) on mounting substrate 130. This would result in a permanent connection between metal terminals 24 of the package(s) and metal terminals 138 of mounting substrate 130.

In the embodiment of Figure 13, packages 10, 90, and 90a of Figures 1, 9, and 13 are shown mounted on mounting substrate 130. In alternative embodiments, however, any package with appropriately arranged posts 18 could be mounted on mounting substrate 130. For example, package 80 of Figure 8A could be mounted on mounting substrate 130. Further, packages with alternative post geometries, such as post geometries 70 or 74 of Figures 6A, 6B, 7A, and 7B, or the post geometries shown in Figure 16(a) through Figure 16(g) or Figure 17(a) through Figure17(f), could also be mounted on mounting substrate 130. In such embodiments, posts 136 of mounting substrate 130 would be complementarily shaped and arranged as appropriate for the post geometry.

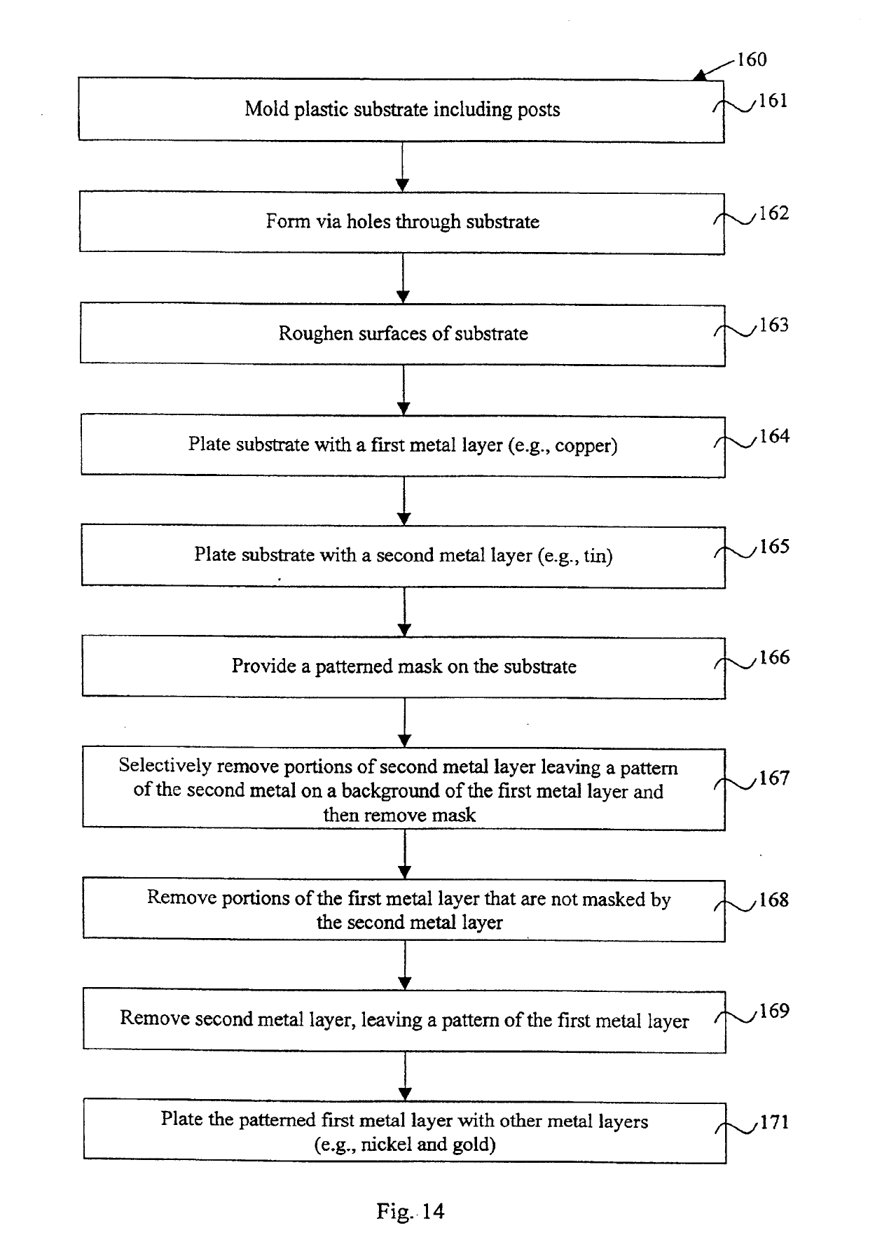

Figure 14 is a flow chart outlining a method 160 of making substrates for integrated circuit packages in accordance with the present invention. Method 160 can be used, for example, to make substrates 12, 12b, 12c, and 12d of packages 10, 80, 90, and 90a of Figures 1, 8A, 9, and 13. Substrates with alternative post geometries, such as post geometries 70 and 74 of Figures 6A and 7A, or those shown in Figure 16(a) through Figure 16(g) or Figure 17(a) through Figure 17(f), can also be made by method 160. Method 160 can also be used to make mounting substrate 52 of Figure 4 and mounting substrate 130 of Figure 13. The following discussion uses substrate 12 as an example, with notable differences mentioned for alternative substrates.

In step 161 of method 160, substrate 12 is formed, for example, by injection molding a plastic material, such as liquid crystal polymer (LCP) or another insulative plastic material. LCP is capable of sustaining high temperatures and is easily molded. The plastic body 16 of substrate 12 is molded along with posts 18. Posts 18 may be formed on both upper and lower sides 20 and 22 of body 16, depending on the embodiment. In addition, a recess 32 may be formed in upper side 20 of body 16 to receive an integrated circuit 14 in a later step. Substrate 12 may be formed individually, or as part of an integral matrix of substrates 12 that will later be cut apart.

In step 162, holes are each formed through body 16 adjacent to posts 18. The holes are each formed between upper side 20 of body 16 and lower side 22 body 16. The holes are for forming vias 30. The holes may be punched or drilled, for example, using a computer-controlled laser drill. Holes may not be needed for some substrates, such as substrate 12d of package 90a, or mounting substrate 130 (see Figure 13).

In step 163, the surfaces of substrate 12 are roughened to aid adhesion of a metal layer to substrate 12 in a subsequent metal plating step. One way to roughen the surfaces of substrate 12 is to expose substrate 12 to a plasma that includes, for example, a fluorocarbon gas or some other fluorine gas, to form numerous very small asperities on the surfaces of substrate 12.

In step 164, all surfaces of substrate 12 are plated with a first metal layer, which may be, for example, copper. The holes formed through body 16 are also plated with copper to form vias 30. The copper may be plated onto substrate 12 using an electroless plating process. Surface roughness induced in step 163 promotes adhesion of the copper layer to substrate 12.

In step 165, the surfaces of substrate 12 are plated with a second layer of metal, which may be tin or another metal.

In step 166, a patterned mask is formed on upper side 20 and lower side 22 of body 16. The mask defines metal terminals 24 and traces 28. The particular process of forming the patterned mask may vary. In an exemplary process, a masking material, such as photoresist or a laser-sensitive or electron beam sensitive masking material, is applied to substrate 12and then baked. Next, selected portions of the masking material are exposed to an energy source, which may be a computer-controlled laser, or an electron beam, or an ultra violet lamp applied through a reticle or a series of reticles. Energy from the source exposes the selected portions of the mask material. Subsequently, a developer is applied to the masking material so that the non-exposed masking material (or the exposed masking material, depending on the method used) may be removed, leaving a patterned mask on substrate 12. The mask patterning process may be done in more than one step, and may use different energy sources on different portions of substrate 12.

In step 167, the tin is etched through openings in the mask, using a liquid chemical etchant, or a plasma etchant, with a high selectivity for tin over copper. After etching the exposed tin, the mask is removed. As a result, patterns of tin are left on the copper background. In particular, patterns of tin remain on posts 18 and in the areas where traces 28 and leadfingers 38 are desired. Conventional etch methods allow the formation of 0.01wide tin lines and 0.01wide spaces between the tin lines, although differently-sized lines and spaces may be used.

In step 168, the copper is removed from all areas of substrate 12 that are not covered by the tin pattern. The tin thus acts as a mask during step 168. The copper may be removed, for example, by exposing the uncovered copper areas of substrate 12 to a laser tuned to vaporize the copper without vaporizing the tin. Alternatively, the mask from step 167 may be left on substrate 12 and the copper may be removed using a liquid chemical, or plasma, etchant, if only traces 28 and leadfingers 38 are being defined. As a result of step 168, metal terminals 24, traces 28, and leadfingers 38, all of which include a first layer of copper covered by a second layer of tin, are defined on substrate 12. Traces 28 are coupled to respective vias 30. Recall vias 30 are also coated with copper, thereby electrically coupling traces 28 to respective metal terminals 24 of posts 18.

In step 169, the tin is removed from substrate 12. The tin may be removed by chemical or plasma etching, using an etchant with a high selectivity for tin over copper.

In step 171, the remaining copper on substrate 12 is optionally plated (e.g., by electroless plating) with additional metal layers, such as an intermediate layer of nickel and a top layer of gold. Nickel promotes the adhesion of the gold to the copper. Gold facilitates bonding of an integrated circuit to traces 28. In addition, friction between the gold layers on metal terminals 24 of posts 18 helps hold packages on mounting substrates (see, for example, Figure 4 and Figure 8B). Gold also helps hold stacked packages together (see, for example, Figure 11 and Figure 13). At the conclusion of step 171, substrate 12 is fully formed and ready for assembly into a package, such as package 10 of Figure 1.

In an alternative embodiment of a method of making substrates for packages in accordance with the present invention, the tin mask layer is not used. In this case, steps 165, 167, and 169 of method 160 are omitted, and the patterning process described above for step 166 is used to pattern the first metal layer directly. For example, a photoresist layer could be used as a mask during laser, liquid chemical, or plasma, etching of the unwanted portions of the copper layer. Alternatively, unwanted portions of the copper layer may be ablated directly by a computer-controlled laser following a pattern that is programmed into software controlling the laser.

A vendor believed to be capable of performing method 160 of Figure 14, or otherwise capable of forming substrate 12 and mounting substrate 52, is Siemens Energy and Automation, Inc., which has offices in Germany; Austin, Texas; and Atlanta, Georgia.

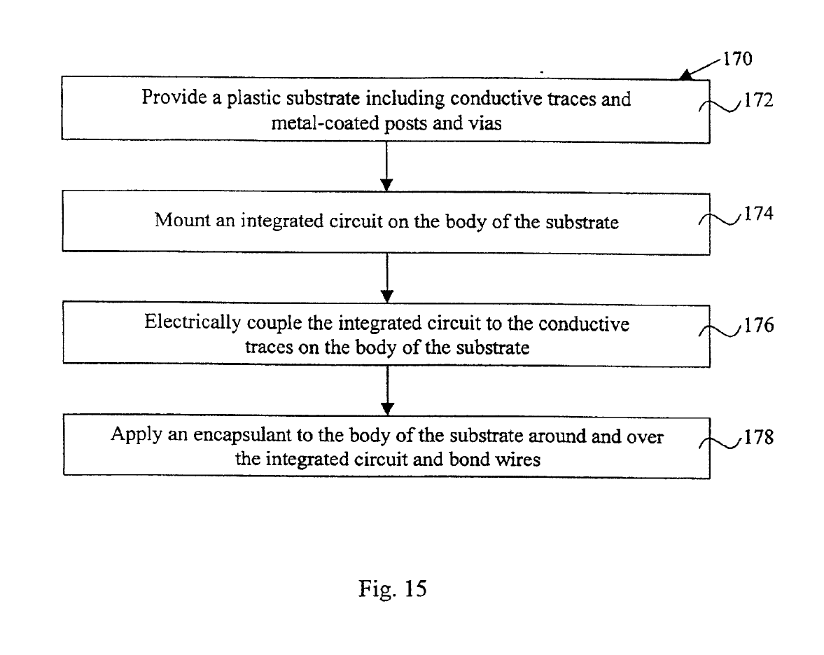

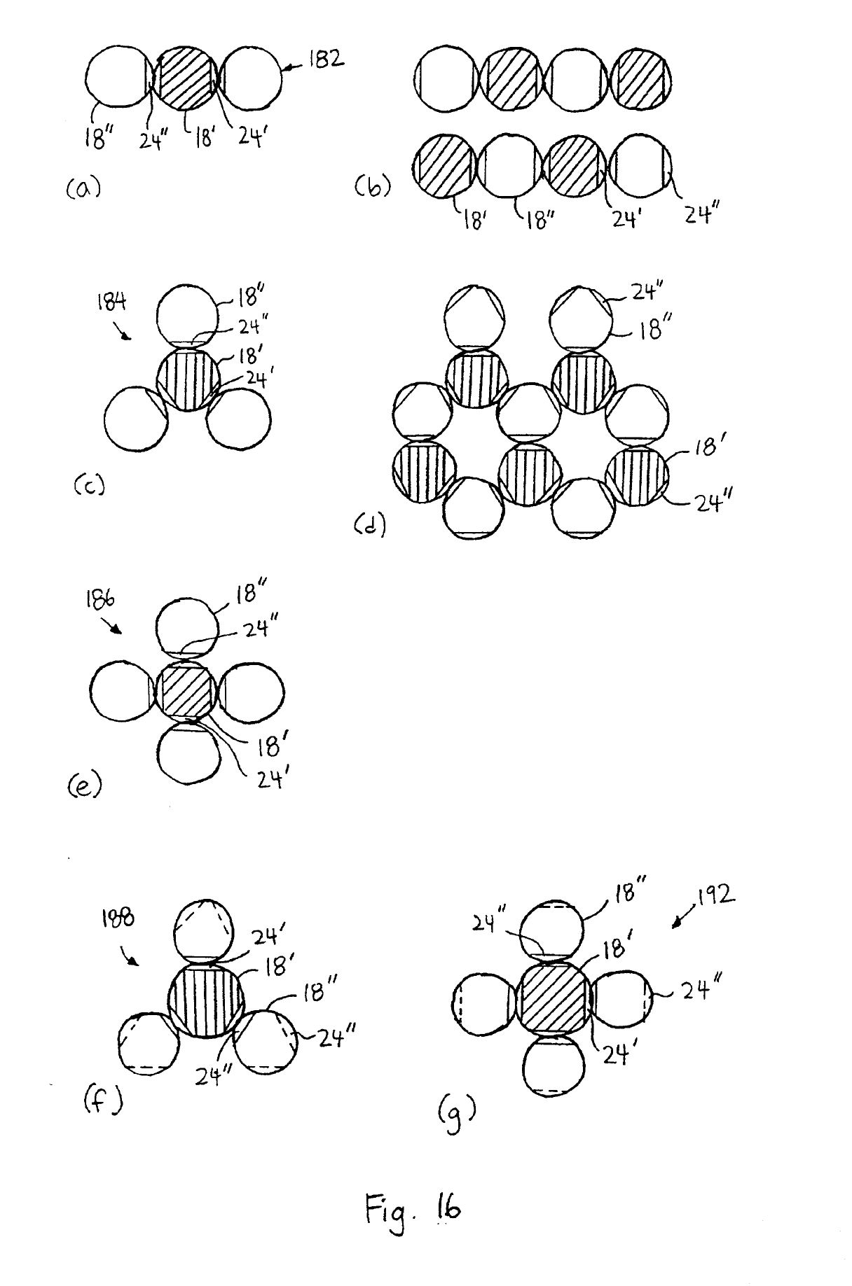

Figure 15 is a flow chart outlining a method 170 of making integrated circuit packages in accordance with the present invention. Method 170 can be used, for example, to make package 10 of Figure 1. In step 172, a substrate 12, which is molded of a plastic material, is provided. Substrate 12 includes conductive traces 28 coupled to metal terminals 24 on posts 18, through vias 30. Substrate 12 may be formed, for example, by method 160 of Figure 14. In step 174, integrated circuit 14 is mounted in recess 32 of upper side 20 of body 16 of substrate 12. If substrate 12 does not include a recess 32, then integrated circuit 14 is centrally mounted on upper side 20. A conventional die attach adhesive or adhesive film may be used to attach integrated circuit 14 to body 16.

In step 176, integrated circuit 14 is electrically coupled to traces 28 of substrate 12 by coupling bond wires 34 between bond pads 36 of integrated circuit 14 and leadfingers 38 of traces 28. Conventional bond wire materials (e.g., gold), wiring methods, and equipment may be used. In step 178, encapsulant 40 is formed over integrated circuit 14, bond wires 34, and leadfingers 38 by applying an insulative encapsulant material onto upper side 20 of body 16. A glob top, liquid encapsulation, or molding method may be used to apply encapsulant 40.

Packages 80, 90, and 90a of Figures 8A, 9, and 13, respectively, may be made by a method similar to method 170 outlined in Figure 15. Our discussion focuses on notable differences in the fabrication methods. In step 172, an appropriate substrate for the specific embodiment would be required. As discussed above, the substrates may be made by a method similar to method 160, outlined in Figure 14. In an exemplary method of package assembly for package 80 of Figure 8A, bond pads 36 of flip chip 82 are directly mounted on traces 28, or metal lands coupled to traces 28, and electrically connected thereto by solder bumps in steps 174 and 176. Subsequently, in step 178, underfill material 88 can be applied onto upper side 20 of body 16 around flip chip 82. Underfill material 88 would wick in under flip chip 82.

In some alternative embodiments of packages 10, 90, and, 90a of Figures 1, 9, and 13, respectively, it is possible that integrated circuit 14 may be mounted using the flip chip configuration described for package 80 of Figure 8A. In these embodiments, the package assembly would be similar to that described above for package 80 of Figure 8A.

An alternative method of making substrates 12, 12b, 12c, and 12d and packages 10, 80, 90, and 90a of Figures 1, 8A, 9, and 13, respectively, is to make a plurality of substrates (and, subsequently, packages) in parallel. Typically, multiple packages with similar substrates are made in parallel. In such an embodiment, a molded sheet of plastic material consisting of an array of interconnected package sites is formed. Each package site of the sheet would include a metallized, patterned substrate for the specific package embodiment being packaged. A method similar to method 160 of Figure 14 could be used to form the sheet, including all package sites of the sheet. Next, a package assembly method similar to method 170 of Figure 15, or similar to the flip chip mounting method discussed above, could be performed in parallel for each package site of the sheet. Finally, the package sites of the sheet would be singulated to form individual packages. One way to singulate assembled packages from the sheet would be to vertically cut through the sheet between the package sites using a saw or laser.

Embodiments of mounting substrates 52 and 130 (e.g., see Figures 4, 8B, 11, and 13) may be made by a method similar to method 160 of Figure 14. Only notable differences in the fabrication methods are discussed here. Step 162 of method 160 may be omitted if mounting substrates 52 or 130 do not include vias 114 or 156, respectively. As discussed above with respect to Figure 14, traces 60 and 144 on mounting substrates 52 and 130, respectively, may be formed with the tin mask described in method 160, or by patterning the copper layer with a conventional photolithography process.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

What is Claimed is:

1.An integrated circuit package comprising:
a molded plastic body;
a plurality of plastic posts each extending integrally from said body;
a plurality of electrically separate metal terminals coating a sidewall of at least one of said posts;
a plurality of electrically conductive paths each electrically coupled to at least one of said metal terminals; and
an integrated circuit including a plurality of bond pads, said integrated circuit mounted on said body and electrically coupled to at least some of said paths through said bond pads.

2.The integrated circuit package of Claim 1, wherein a total number of said posts is less than a total number of said bond pads.

3.The integrated circuit package of Claim 1, wherein said posts are arranged in a checkerboard pattern.

4.The integrated circuit package of Claim 1, wherein a shape of at least some of said posts comprises a cylinder.

5.The integrated circuit package of Claim 1, wherein a shape of at least some of said posts is substantially cylindrical and includes at least one projection.

6.The integrated circuit package of Claim 5, wherein an exterior surface of said projection is coated by a respective one of said metal terminals.

7.The integrated circuit package of Claim 1, wherein a shape of at least some of said posts comprises hexagonal.

8.The integrated circuit package of Claim 1, further comprising a plurality of bond wires each electrically coupled between said bond pads and at least some of said paths.

9.The integrated circuit package of Claim 1, further comprising an encapsulant material covering at least a part of said integrated circuit.

10.The integrated circuit package of Claim 1, wherein said integrated circuit comprises a flip chip.

11.A stack of integrated circuit packages, the stack comprising:
a first integrated circuit package including a first integrated circuit mounted on a first molded plastic body of a first substrate, said first substrate including a plurality of first plastic posts extending integrally from said first molded plastic body and a plurality of electrically separate first metal terminals coating a sidewall of at least one of said first plastic posts; and
a second integrated circuit package including a second integrated circuit mounted on a second molded plastic body of a second substrate, said second substrate including a plurality of second plastic posts extending integrally from said second molded plastic body and a plurality of electrically separate second metal terminals coating a sidewall of at least one of said second plastic posts,
wherein said first and second integrated circuit packages are stacked, and at least some of said first plastic posts are engaged with at least some of said second plastic posts so that said first metal terminals are electrically coupled to respective ones of said second metal terminals.

12.The stack of Claim 11, wherein said first integrated circuit and said second integrated circuit face a same direction.

13.The stack of Claim 11, wherein said first integrated circuit and said second integrated circuit face each other.

14.The stack of Claim 11, wherein a first subset of said first plastic posts of said first integrated circuit package are arranged in a first checkerboard pattern on a first side of said first molded plastic body, and a second subset of said first plastic posts are arranged in a complementary second checkerboard pattern on a second side of said first molded plastic body.

15.The stack of Claim 14, wherein said first integrated circuit package further includes a plurality of vias each extending through said first molded plastic body, each said via electrically coupling one of said first metal terminals from said first subset of first plastic posts to a respective one of said first metal terminals from said second subset of first plastic posts.

16.An electronic assembly comprising:
a first integrated circuit package including a first integrated circuit mounted on a first molded plastic body of a first substrate, said first substrate including a plurality of first plastic posts extending integrally from said first molded plastic body and a plurality of electrically separate first metal terminals coating a sidewall of at least one of said first plastic posts; and
a molded plastic substrate including a plurality of metal-coated posts extending integrally from said plastic substrate, wherein said metal-coated posts are engaged with said first plastic posts and are electrically coupled to said first metal terminals.

17.The electronic assembly of Claim 16, wherein said molded plastic substrate comprises a part of a second integrated circuit package, said second integrated circuit package including a second integrated circuit mounted on said molded plastic substrate and electrically coupled to said metal-coated posts.

18.The electronic assembly of Claim 16, wherein said molded plastic substrate further comprises a plurality of input/output terminals adapted to be electrically coupled to circuitry external to said molded plastic substrate.

19.A substrate for mounting one or more integrated circuit packages, said substrate comprising:
a molded plastic sheet;
a plurality of plastic posts each extending integrally from said sheet;
a plurality of electrically separate metal terminals coating a sidewall of at least one of said posts;
a plurality of electrically conductive input/output terminals at a periphery of said sheet, said input/output terminals adapted to electrically couple said substrate to circuitry external to said substrate; and
a plurality of electrically conductive traces each electrically coupled at first ends to a respective one of said metal terminals, wherein at least some of said traces are electrically coupled at opposite second ends to respective ones of said electrically conductive input/output terminals.
20.The substrate of Claim 19, wherein said electrically conductive input/output terminals comprise a plurality of metal lands or balls on, or a plurality of metal pins extending from, a lower side of said sheet.

20. 21.The substrate of Claim 19, wherein said posts extend from a first side of said sheet and from an opposite second side of said sheet.

21. 22.The substrate of Claim 21, further including one or more vias extending through said sheet and electrically coupled between respective metal terminals on respective posts on said first and second sides of said sheet.

22. 23.The substrate of Claim 21, wherein said electrically conductive input/output terminals comprise a second plurality of conductive traces on a connector extending integrally from said sheet.
